(19) United States
(12) Patent Application Publication
(10) Pub. No.: US 2006/0205129 A1
(43) Pub. Date: Sep. 14, 2006

(54) Method for manufacturing semiconductor device

(75) Inventors: Tomohiko Sato, Atsugi (JP); Shigeharu Monoe, Tochigi (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 11/359,470

(22) Filed: Feb. 23, 2006

(30) Foreign Application Priority Data
Feb. 25, 2005 (JP) 2005-051169

(51) Int. Cl. H01L 21/8234

(52) U.S. Cl. 438/197

(57) ABSTRACT

In a gas containing a fluorine atom in the molecule, etching of a SiN film is performed isotropically; therefore, the width of a sidewall gets smaller and it is difficult to widen the width of an LDD region. A silicon nitride film is formed over a gate electrode, a hydrogen bromide is mainly used as an etching gas, the silicon nitride film only over the gate electrode and the surface of a substrate are removed by an etching method such as ICP (Inductively Coupled Plasma), and the silicon nitride film is simultaneously left only on the side surface part of the gate electrode.

### BACKGROUND OF THE INVENTION

1. Field of the Invention

The present invention relates to a method for forming a sidewall formed of silicon nitride on a side surface of a gate electrode, and to a semiconductor device manufactured through this process and a manufacturing method thereof in a manufacturing process of a thin film transistor (TFT).

2. Description of the Related Art

Research and development have been widely conducted on size reduction and high integration of semiconductor elements. In particular, a technique for reducing the size of a MOS transistor has been remarkably advanced. MOS is an acronym of Metal-Oxide-Semiconductor, which shows a structure in which three kinds of materials (substances) of metal, oxide, and a semiconductor are combined.

Here, the metal includes not only pure metal but also a semiconductor material having sufficiently high conductance, an alloy of a semiconductor and metal, or the like. The oxide includes not only pure oxide but also an insulating material having sufficiently high resistance, such as nitride. Even in such cases, the term MOS is applied in general. Hereinafter in this specification, an electric-field effect element having such a structure including nitride and other insulating materials is referred to as a MOS transistor.

Either an N-channel or P-channel MOS transistor generally includes a channel formation region, a gate insulating film, a gate electrode, a source region, and a drain region. Since this MOS transistor can be highly integrated easily, the MOS transistor is widely used as a transistor element having an integrated circuit.

A MOS transistor is reduced in size by narrowing the width of its gate electrode. With the size reduction of a MOS transistor, an LDD (Lightly Doped Drain) structure in which a drain region on a channel formation region side is lightly doped with impurities is used to prevent a short-channel effect or hot electron generation.

By employing the LDD structure, the amount of impurities diffusing into the drain region on the channel formation region side can be decreased and the length of a channel length can be secured. Moreover, since the gradient of impurity concentration distribution in a pn junction portion formed at a boundary between a channel formation region and an impurity region (drain region) can be relieved, electric-field concentration can be relieved in this region. Accordingly, this allows stabilization of operation of an element.

In forming an LDD region, a sidewall is formed on the both sides of the gate electrode. In the case of forming a sidewall with silicon nitride (SiN), etching is performed with an RIE (Reactive Ion Etching) type dry etching apparatus with the use of a fluorine-based gas such as SF₆ or CF₄.

In etching a silicon nitride film, a gas containing a fluorine atom such as CF₄, a mixed gas of CF₄ and O₂, NF₃, CH₂, or F₂ is conventionally used.

In manufacturing a semiconductor device, optimum disposition and dimension are designed from the point of view of a structure and an electrical characteristic. As for the point of view of a structure, an active element such as a transistor constituting a semiconductor device, a passive element such as a resistor or a capacitor, element isolation for electrically isolating elements from each other, and further a wiring or the like are designed what the structure is like. In this case, the dimension is determined in accordance with a rule or the like regarding each minimum pattern dimension. In addition, as for an electrical characteristic, it is necessary to consider a transistor characteristic, overlap capacitance of a gate electrode with a source region and with a drain region, resistance of the gate electrode with the source region and with the drain region, resistance of the source region with a drain electrode, resistance or parasitic capacitance of a wiring, contact resistance of a contact hole, or the like.

Therefore, it is necessary to manufacture a semiconductor device as designed to optimize the performance of a semiconductor device.

However, when etching of a silicon nitride film is performed with an RIE apparatus with the use of a gas containing a fluorine atom, the etching of a silicon nitride film is performed isotropically. Therefore, the silicon nitride film cannot be left only on the side surface of the gate electrode to have the same width as the thickness of the silicon nitride film before the etching.

For example, when a silicon nitride film in 300 nm thick is formed over a gate electrode in 400 nm thick and an etching process is performed with the use of a mixed gas of SF₆ and CF₄, the width of a sidewall becomes 100 nm or less. The width of an LDD region manufactured with the use of this sidewall also gets smaller.

### SUMMARY OF THE INVENTION

It is an object of the present invention to solve the above problem of the conventional technique. The object is to suppress change of a sidewall in dimension in etching a silicon nitride film and thus to enhance processing precision in forming an LDD region.

Thus, the present invention has the following structure in order to achieve the above object.

According to one feature disclosed in the present invention, a method for manufacturing a semiconductor device includes the steps of forming a gate electrode over a semiconductor film; forming a silicon nitride film over this gate electrode; and forming a sidewall made of silicon nitride on the side surface of the gate electrode while removing the silicon nitride film over the gate electrode and the semiconductor film by performing dry etching with the use of a mixed gas mainly containing hydrogen bromide (HBr). The mixed gas mainly containing hydrogen bromide described here is defined as follows. A mixed gas mainly containing hydrogen bromide (HBr) means a ratio of a flow rate of a hydrogen bromide gas is greater than or equal to 50% based on the total flow rate of the mixed gas.

In addition, according to another feature of the present invention, a method for manufacturing a semiconductor device includes the steps of forming a gate electrode over a semiconductor film; forming a silicon nitride film over this gate electrode; selectively etching the silicon nitride film with the use of a mixed gas containing hydrogen bromide (HBr)and chlorine (Cl₂), and forming a sidewall made of the silicon nitride on the side surface of the gate electrode. Note that a ratio of a flow rate of a hydrogen bromide gas is greater than or equal to 50% based on the total flow rate of the mixed gas. In addition, according to another feature of the present invention, a method for manufacturing a semiconductor device includes the steps of forming a gate electrode over a semiconductor film; forming a silicon nitride film over the gate electrode; and etching the silicon nitride film by a mixed gas to leave a part of the silicon nitride film on side surfaces of the gate electrode, which the mixed gas contains a hydrogen bromide gas and a chlorine gas and oxygen. Note that a ratio of a flow rate of a hydrogen bromide gas is greater than or equal to 50% based on the total flow rate of the mixed gas.

Note that, in the above structure, a semiconductor film is formed over a substrate made of an insulating substance. As an example of the substrate made of an insulating substance, a glass substrate such as an alumino borosilicate glass or a barium borosilicate glass, a quartz substrate, a ceramic substrate, a stainless steel substrate, a substrate made of plastic or synthetic resin such as acryl can be given.

Moreover, according to another feature of the present invention, a method for manufacturing a semiconductor device includes the steps of forming a gate electrode over a semiconductor substrate; forming a silicon nitride film over this gate electrode; and forming a sidewall made of silicon nitride on the side surface of the gate electrode while removing the silicon nitride film over the gate electrode and the semiconductor substrate by performing dry etching with the use of a mixed gas mainly containing hydrogen bromide (HBr). The mixed gas mainly containing hydrogen bromide includes chlorine (Cl₂).

Further, according to another feature of the present invention, a method for manufacturing a semiconductor device includes the steps of forming a gate electrode over a semiconductor substrate; forming a silicon nitride film over this gate electrode; selectively etching the silicon nitride film with the use of a mixed gas containing hydrogen bromide (HBr) and chlorine (Cl₂) and oxygen (O₂); and forming a sidewall made of silicon nitride on the side surface of the gate electrode. Note that a ratio of a flow rate of a hydrogen bromide gas is greater than or equal to 50% based on the total flow rate of the mixed gas.

Note that, in the above structure, a single-crystal silicon substrate or a compound semiconductor substrate, or an SOI (Silicon on Insulator) substrate can be used as a semiconductor substrate. An N-type or P-type single-crystal silicon substrate, a GaAs substrate, an InP substrate, a GaN substrate, an SiC substrate, a sapphire substrate, a ZnSe substrate, or the like can be typically given as the single-crystal silicon substrate. A substrate manufactured using a pasting method, an SIMOX (Separation by Implanted Oxygen) method, or the like can be typically given as the SOI substrate.

Note that, in the above structures, a dry etching method such as parallel plate type RIE (Reactive Ion Etching), magnetron type RIE, two cycles type RIE, microwave type RIE, ECR (Electron Cyclotron Resonance) plasma etching, helicon type plasma etching, or ICP (Inductively Coupled Plasma) type plasma etching is used for the etching method.

When the above etching method is used with the use of a gas containing hydrogen bromide, this gas is accelerated by a high frequency after being decomposed by plasma and physically collided with the surface of a silicon nitride film to react with the silicon nitride film. Horizontal etching is blocked by silicon bromide adhering to a side wall. Consequently, anisotropic etching can be performed.

In addition, a thin film transistor (TFT) is formed according to the present invention, and a CPU (Central Processing Unit), a memory, an IC, an RFID element, a pixel, a driver circuit, and the like can be typically given as an example of a semiconductor device using this TFT. Further, it is also possible to form various electronic devices such as a television, a computer, or a portable information terminal by incorporating these semiconductor devices.

According to the present invention, higher anisotropy can be obtained in etching a silicon nitride film compared with the case where a gas containing a fluorine atom is used. Therefore, there can be less dimensional change in width of a sidewall when the silicon nitride film is etched. Further, it is possible to form an LDD region preferably in accordance with this sidewall.

These and other objects, features and advantages of the present invention will become more apparent upon reading of the following detailed description along with the accompanied drawings.

### BRIEF DESCRIPTION OF THE DRAWINGS

In the accompanying drawings:

FIGS. 1A to 1F are explanatory views of an etching method according to the present invention;

FIGS. 2A to 2D are each a substitute photograph of a cross-sectional states in an etching process according to the present invention;

FIGS. 3A to 3D are views of the substitute photographs shown in FIGS. 2A to 2D;

FIGS. 4A to 4D are views each showing a manufacturing process of a semiconductor element according to the present invention;

FIGS. 5A to 5D are views each showing a manufacturing process of a semiconductor element according to the present invention;

FIGS. 6A to 6D are views each showing a manufacturing process of a semiconductor element according to the present invention;

FIGS. 7A to 7C are views each showing a manufacturing process of a semiconductor element according to the present invention;

FIGS. 8A to 8E are views each showing a manufacturing process of a CMOS-type IC according to the present invention;

FIGS. 9A to 9C are views each showing a manufacturing process of a CMOS-type IC according to the present invention;

FIGS. 10A to 10D are views each showing a manufacturing process of a CMOS-type IC according to the present invention;

FIGS. 11A to 11C are views each showing a manufacturing process of a CMOS-type IC according to the present invention;

FIGS. 12A to 12D are views each showing a manufacturing process of a wireless IC tag according to the present invention;

FIGS. 13A to 13D are views each showing a manufacturing process of a wireless IC tag according to the present invention;

FIGS. 14A to 14C are views each showing a manufacturing process of a wireless IC tag according to the present invention;

FIGS. 15A to 15C are views each showing a manufacturing process of a wireless IC tag according to the present invention;

FIGS. 16A and 16B are views each showing a manufacturing process of a wireless IC tag according to the present invention;

FIGS. 17A and 17B are views each showing an example of a method for using a wireless IC tag manufactured according to the present invention;

FIGS. 18A and 18B are views each showing an example of a method for using a wireless IC tag manufactured according to the present invention;

FIG. 19 is a flow chart showing an information processing method of a wireless IC tag manufactured according to the present invention;

FIG. 20 is a view showing an example of a method for using a wireless IC tag manufactured according to the present invention;

FIGS. 21A to 21F are views each showing an example of electronic devices manufactured according to the present invention;

FIGS. 22A to 22D are views each showing a process of manufacturing a sample for etching a silicon nitride film by changing the concentration of a hydrogen bromide gas;

FIGS. 23A and 23B are views each showing an etching state of a silicon nitride film by using the sample manufactured in FIGS. 22A to 22D;

FIGS. 24A and 24B are a table and a graph each showing a width of a sidewall formed by etching a silicon nitride film by changing the concentration of a hydrogen bromide gas;

FIGS. 25A to 25C are each a substitute photograph at the end of etching;

FIGS. 26A to 26D are views each showing a manufacturing process of a photo IC manufactured according to the present invention;

FIGS. 27A to 27D are views each showing a manufacturing process of a photo IC manufactured according to the present invention;

FIGS. 28A to 28C are views each showing a manufacturing process of a photo IC manufactured according to the present invention;

FIGS. 29A and 29B are views each showing a manufacturing process of a photo IC manufactured according to the present invention;

FIGS. 30A to 30C are views each showing a manufacturing process of a photo IC manufactured according to the present invention; and

FIGS. 31A and 31B are views each showing a manufacturing process of a photo IC manufactured according to the present invention.

### DETAILED DESCRIPTION OF THE INVENTION

Hereinafter, embodiment mode of the present invention will be explained with reference to drawings. However, it is to be easily understood that various changes and modifications will be apparent to those skilled in the art. Therefore, unless such changes and modifications depart from the invention, they should be construed as being included therein.

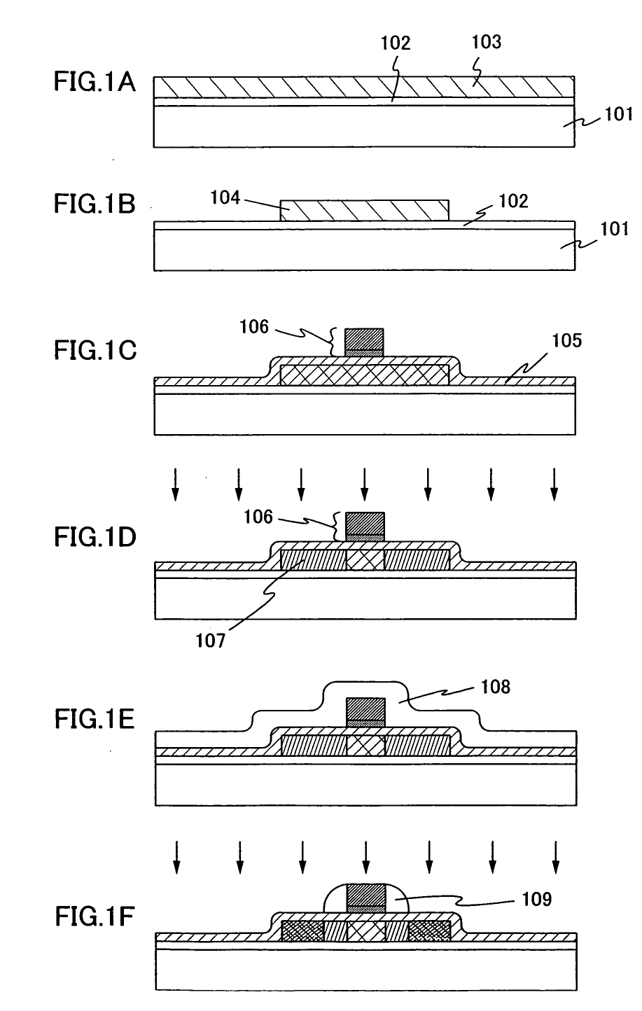

Embodiment mode of the present invention will be explained with reference to FIGS. 1A to 1F.

First, as shown in FIG. 1A, a base film 102 formed of an insulating substance containing silicon as the main component is formed over an insulating substrate 101. Here, as the insulating substrate 101, a glass substrate such as a barium borosilicate glass or an alumino borosilicate glass, a quartz substrate, a ceramic substrate, a stainless steel substrate, or a substrate made of plastic typified by PET (polyethylene terephthalate), PES (polyethersulfone resin), or PEN (polyethylene naphthalate) or synthetic resin typified by acryl as a raw material can be used. Further, an amorphous semiconductor film 103 is formed over the base film 102.

A crystalline semiconductor film is obtained by laser irradiation to the amorphous semiconductor film 103, and an island-shaped semiconductor film 104 is formed by performing a process (patterning) to form this crystalline semiconductor film into a predetermined shape. Note that, in the crystallization of the amorphous semiconductor film 103, not only laser irradiation but also a furnace annealing method using an electrically heated furnace, a rapid thermal annealing method (RTA) using of a lamp, or the like can be used.

Next, a gate insulating film 105 is formed to cover the semiconductor film 104. The gate insulating film 105 is formed in thickness of 40 nm or more and 150 nm or less with the use of a plasma CVD method or a sputtering method. Tantalum nitride (TaN) and tungsten (W) are formed thereover as a conductive film to be 400 nm in total with the use of a plasma CVD method or a sputtering method. Then, a gate electrode 106 is formed by forming this conductive film into a predetermined shape.

Then, in the case of forming an N-channel TFT, ion implantation of phosphorus (P) is preformed into the semiconductor film 104 to form a low-concentration N-type region 107. In this case, the gate electrode 106 serves as a mask in performing the ion implantation; therefore, the N-type region is formed in a self-aligned manner with the gate electrode 106. Similarly, in the case of forming a P-channel TFT, ion implantation of boron (B) is performed to the semiconductor film 104 into form a low-concentration P-type region.

The time when etching finishes is determined by observing a waveform of an emission spectrum of plasma as etching time passes. In other words, when a silicon nitride film is etched, the end of etching is determined by grasping the change of the emission intensity of emitted etching gas or a generated reaction product.

In the case of forming a sidewall 109, first, a silicon nitride film 108 formed over the gate electrode or the substrate is gradually etched. The intensity of an emission spectrum at this step is constant. When etching is further continued, the silicon nitride film over the gate electrode or the substrate is etched completely and thus the silicon nitride film remains only on the side surface portion of the gate electrode. In such as state, the emission intensity gets weaker than beginning of the etching. The end of the etching is determined by grasping the change in emission intensity.

### Embodiment 1

A method for manufacturing a semiconductor element will be explained with reference to drawings. Note that the case of forming a semiconductor film in an insulating substrate and manufacturing a TFT with the use of this semiconductor film is shown in this embodiment.

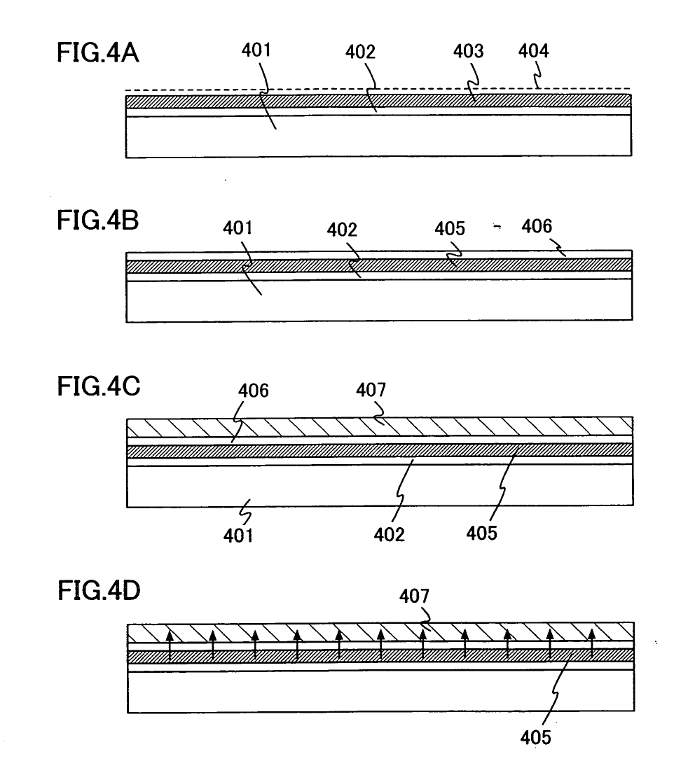

As shown in FIG. 4A, a base film 402 is formed over a substrate 401 having an insulating surface. In this embodiment, a glass substrate is used as the substrate 401. Note that, as the substrate used here, a glass substrate such as a barium borosilicate glass or an alumino borosilicate glass, a quartz substrate, a ceramic substrate, a stainless steel substrate, or the like can be used. In addition, a substrate made from plastic typified by PET (polyethylene terephthalate), PES (polyethersulfone resin), or PEN (polyethylene naphthalate) or synthetic resin such as acryl as a raw material tends to have lower heat resistance than another substrate. Such a substrate can be used, as long as the substrate can resist the treatment temperature in the manufacturing process.

The base film 402 is provided to prevent an alkali metal such as natrium contained in the substrate 401 from diffusing into a semiconductor and adversely affecting the characteristic of a semiconductor element. Therefore, the base film 402 is formed with an insulating substance such as silicon oxide, silicon nitride, or silicon nitride oxide which can suppress the diffusion of an alkali metal or an alkaline-earth metal into the semiconductor. In addition, the base film 402 may be formed in a single layer or multilayer structure. In this embodiment, a silicon nitride oxide film is formed with the use of a plasma CVD (Chemical Vapor Deposition) method in thickness of 10 nm or more and 400 nm or less.

In the case of using the substrate containing even a slight amount of the alkali metal or the alkaline-earth metal such as the glass substrate or the plastic substrate, it is effective to provide the base film for preventing the diffusion of the impurities. When a substrate such as a quartz substrate is used which hardly diffuses the impurities, the base film is not necessarily provided.

Next, an amorphous semiconductor film 403 is formed over the base film 402. The amorphous semiconductor film 403 is formed in thickness of 10 nm or more and 100 nm or less (preferably, 30 nm or more and 60 nm or less) by a known method (a sputtering method, an LPCVD method, a plasma CVD method, or the like). The amorphous semiconductor film 403 used here may be formed with silicon or silicon germanium. Silicon is used in this embodiment. When silicon germanium is used, it is preferable that the concentration of germanium is approximately 0.01 atomic % or more and 4.5 atomic % or less.

In order to obtain a favorable crystalline structure, an impurity element such as oxygen or nitrogen in the amorphous semiconductor film 403 preferably have a concentration reduced to 5×10¹⁸ atomic/cm³ or less. In addition, it is preferable to form the base film 402 and the amorphous semiconductor film 403 continuously without exposing to air because the interface can be prevented from being contaminated.

Then, a solution containing a metal element typified by nickel (Ni) (a water solution or an acetic acid solution) is coated all over the amorphous semiconductor film 403 with a spin coating method or a dip coating method to form a film 404 containing a metal element. Note that, since this film is extremely thin, the film sometimes cannot be observed as a film. In this embodiment, a nickel acetic acid solution containing nickel of 1 ppm or more and 100 ppm or less by weight is coated all over by a spin coating method. In addition, a method for forming the film 404 containing a metal element is not limited to this method, and a plasma CVD method, a sputtering method, and vapor deposition method can also be used.

In this case, in order to enhance wettability of the amorphous semiconductor film 403 and the nickel acetic acid solution and to spread the solution over the entire surface of the amorphous semiconductor film 403, it is preferable to form an oxide film in thickness of 1 nm or more and 5 nm or less over the amorphous semiconductor film 403 by performing irradiation of ultraviolet light in an oxygen atmosphere, a thermal oxidation method, treatment with the use of ozone water containing a hydroxyl radical or hydrogen peroxide, or the like before coating the nickel acetic acid solution all over. The water solution containing a metal element can be coated over the semiconductor film 403 uniformly by forming the thin oxide film in such a manner.

Note that, although nickel (Ni) is used as a catalyst element in this embodiment, besides, an element such as germanium (Ge), iron (Fe), palladium (Pd), tin (Sn), lead (Pb), cobalt (Co), platinum (Pt), copper (Cu), or gold (Au) may also be used.

Then, heat treatment for crystallizing the amorphous semiconductor film 403 is performed to form a first semiconductor film. As a method for the heat treatment, an annealing furnace using a electrothermal furnace, a rapid thermal annealing method (an LRTA method) using a lamp such as a halogen lamp, a metal halide lamp, a xenon arc lamp, a carbon arc lamp, a high-pressure sodium lamp, or a high-pressure mercury lamp, or a thermal annealing method using heated gas (a GRTA method) can be employed.

Furthermore, in order to improve crystallinity of the first semiconductor film to repair defects remaining in crystal grains, the first semiconductor film is preferably irradiated with laser light or intense light having the same intensity as laser light. In this embodiment, the first semiconductor film is irradiated with laser light with the use of a known laser-annealing device.

The metal element remains in a second semiconductor film 405 which is formed through the above steps. Thus, gettering of the catalyst element existing in the second semiconductor film 405 is performed. The metal element existing in the semiconductor film can be removed by gettering; therefore, off current can be reduced.

First, an oxide film 406 is formed over the surface of the second semiconductor film 405 as shown in FIG. 4B. By forming the oxide film 406 having a thickness of approximately 1 nm or more and 10 nm or less, the surface of the second semiconductor film 405 can be prevented from being damaged due to etching in the subsequent etching step. Note that the oxide film 406 can be formed using a known method. For example, the oxide film 406 may be formed by oxidizing the surface of the second semiconductor film 405 with a water solution in which hydrogen peroxide water is mixed with sulfuric acid, hydrochloric acid, nitric acid, or the like, or ozone water. Alternatively, the oxide film 406 may be formed by plasma treatment in an atmosphere containing oxygen, heat treatment, ultraviolet ray irradiation, or the like. In addition, the oxide film 406 may be formed separately with the use of a plasma CVD method, a sputtering method, a vapor deposition method, or the like.

Next, as shown in FIG. 4C, a semiconductor film 407 for gettering containing a rare gas element of 1×10²⁰ atoms/cm³ or more in concentration is formed over the oxide film 406 with the use of a sputtering method in thickness of 25 nm or more and 250 nm or less. It is desirable that the density of the semiconductor film 407 is lower that that of the second semiconductor film 405 in order to increase the etching selection ratio of the semiconductor film 407 to the second semiconductor film 405. As the rare gas element, one or more kinds of helium (He), neon (Ne), argon (Ar), krypton (Kr), and xenon (Xe) is used.

Then, gettering is performed with heat treatment by using a furnace annealing method or an RTA method as shown in FIG. 4D. When gettering is performed with a furnace annealing method, heat treatment the temperatures of which are at 450° C. or more and 600° C. or less is performed in a nitrogen atmosphere for 0.5 to 12 hours. In addition, when an RTA method is used, a light source of a lamp for heating is lighted for 1 to 60 seconds, preferably 30 to 60 seconds, and repeated for 1 to 10 times, preferably 2 to 6 times. The emission intensity of the light source of the lamp is set arbitrarily; however, the second semiconductor film 405 is made to be heated up to temperatures approximately at 600° C. or more and 1000° C. or less, preferably 700° C. or more and 750° C. or less.

According to the heat treatment, the catalyst element in the second semiconductor film 405 moves to the semiconductor film 407 for gettering due to diffusion as shown in an arrow and thus gettering thereof is performed.

Subsequently, the semiconductor film 407 for gettering is etched and removed selectively. In etching, dry etching using ClF₃ without plasma or wet etching using an alkaline solution such as a water solution containing hydrazine or tetraethyl ammonium hydroxide ((CH₃)₄NOH) can be performed. In this case, the second semiconductor film 405 can be prevented from being etched due to the oxide film 406.

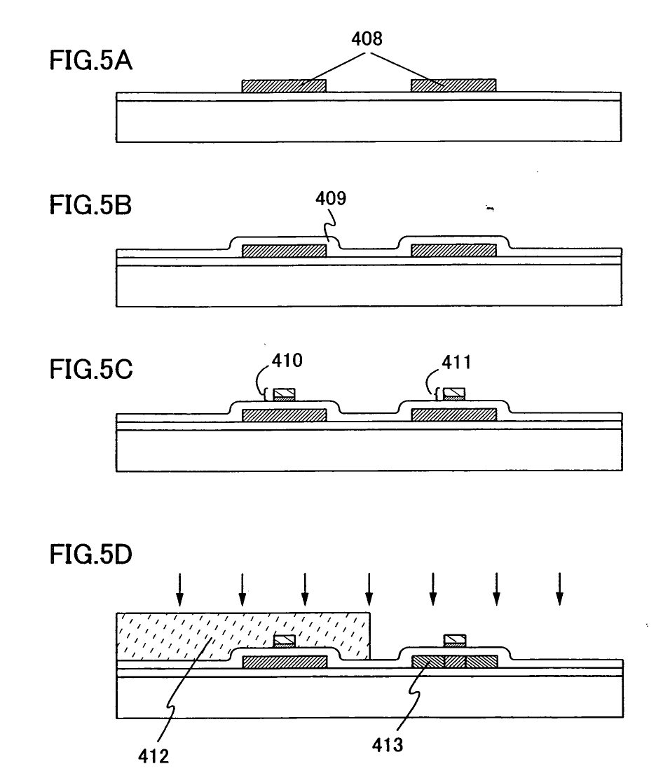

Next, after removing the oxide film 406 with hydrofluoric acid, the second semiconductor film 405 is formed into a predetermined shape and an island-shaped semiconductor film 408 is formed (FIG. 5A). Various semiconductor elements typified by a TFT can be formed using the semiconductor film 408 formed here. Note that, in the present invention, the gettering step is not limited to the method shown in this embodiment. It may be made to reduce the semiconductor film with the use of another method.

The crystalline semiconductor film 408 thus formed is in crystals with a long and thin stick or with a long, thin, and flat shape due to action of the metal element. When each crystal is seen in broad perspective, the crystals are grown in a predetermined direction.

Then, the semiconductor film 408 is added with boron (B) (channel dope). For example, a doping method or an ion implantation method can be used. According to this process, a threshold value that is a semiconductor characteristic can be brought as close as to zero. In other words, the crystalline semiconductor film can further be an intrinsic state as much as possible.

Subsequently, a gate insulating film 409 is formed to cover the semiconductor film 408. The gate insulating film 409 is formed with the use of a plasma CVD method or a sputtering method in thickness of 40 nm or more and 150 nm or less. Note that the gate insulating film 409 may be an insulating film at least containing oxygen or nitrogen, or may also be a single layer or a multilayer. In this embodiment, silicon nitride containing oxygen (SiNO) and silicon oxide containing nitrogen (SiON) are deposited continuously with the use of a plasma CVD method to have a 115 nm thick in total. Note that the gate insulating film 409 is not limited to these materials, and a high dielectric constant substance (also referred to as a high-k material) such as tantalum oxide, hafnium oxide (HfO₂), nitrided hafnium silicon oxide (HfSiON), zirconium oxide (ZrO₂), or aluminum oxide (Al₂O₃), or rare-earth oxide such as lanthanum oxide (La₂O₂) can also be used.

Note that, in the case of forming a TFT having a channel length of 1 μm or less (also referred to as a submicron TFT), the gate insulating film 409 is desirably formed in thickness of 10 nm or more and 50 nm or less.

Next, a conductive film is formed over the gate insulating film 409 and patterned to form gate electrodes 410 and 411 in the following manner. The material of the conductive film formed over the gate insulating film 409 may be a film having conductivity. In this embodiment, a film in which TaN (tantalum nitride) is formed in 30 nm thick and further W (tungsten) is formed in 370 nm thick is used. A resist mask for patterning this conductive film is formed, and the gate electrodes 410 and 411 are formed by forming the conductive film into a predetermined shape with this resist mask.

Note that, without limitation thereto, a conductive film formed by sequentially stacking Mo (molybdenum), Al (aluminum), and Mo or a conductive film formed by sequentially stacking Ti (titanium), Al, and Ti may also be used. In addition, one or more elements of gold (Au), silver (Ag), copper (Cu), platinum (Pt), aluminum (Al), molybdenum (Mo), tungsten (W), and titanium (Ti), or an alloy material or a compound material containing such an element as the main component can be used. Further, a multilayer film of these materials may also be used. When the gate electrodes 410 and 411 are formed using a material made from the above metal in the case of particularly forming the gate insulating film 408 with the use of the above high dielectric constant substance (high-k material), the depletion of the gate electrodes 410 and 411 can be reduced and a large amount of current can flow so that lower power consumption of a semiconductor element can be achieved.

The conductive film is formed over the gate insulating film 409, and further the resist mask for patterning this conductive film is formed. In the step, a photoresist is coated all over the conductive film by a spin coating method or the like and exposed to light. Then, heat treatment (prebake) is performed to the photoresist. The temperature of the prebake is set to 50 to 120° C., which is lower than the temperature of postbake which will be subsequently performed. In this embodiment, the heat temperature is set to 90° C. and the heat time is set to 90 seconds.

After the light-exposure of the photoresist, the photoresist is developed by dropping a developing solution onto the photoresist or spraying the developing solution from a spray nozzle.

The postbake is then performed to the developed photoresist at 125° C. for 180 seconds so that moisture or the like remaining in the resist mask is removed and the stability against the heat is increased at the same time. Through these steps, a resist mask is formed. With this resist mask, the conductive film is patterned to form the gate electrodes 410 and 411.

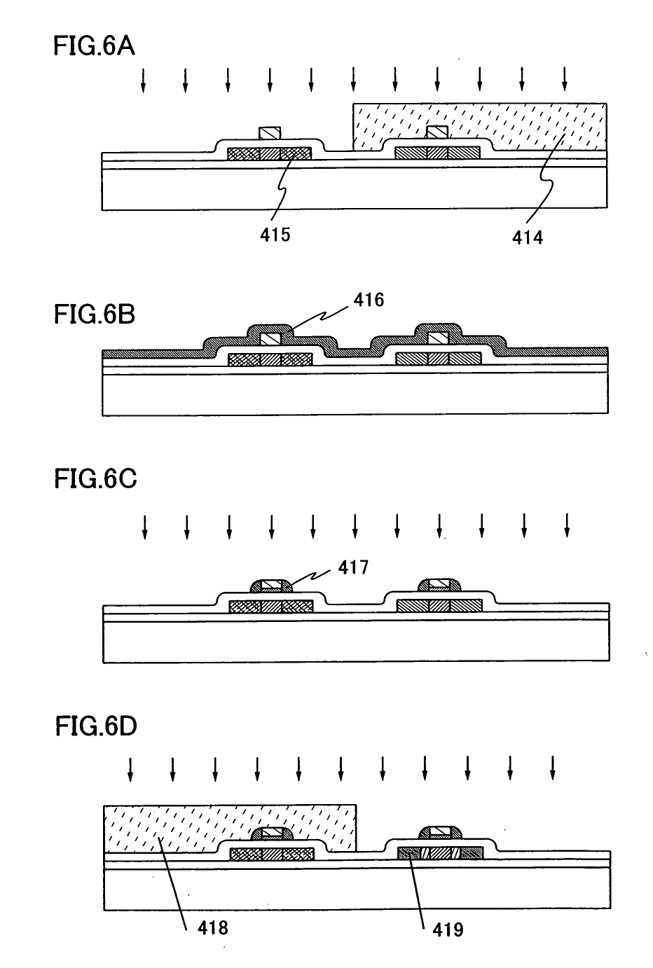

Then, a portion where a P-channel TFT is formed is covered with a resist 412 and arsenic (As) or phosphorus (P) which is an N-type impurity is introduced to form an N-type impurity region 413 (FIG. 5D). In this embodiment, phosphine (PH₃) is introduced in the range of 60 to 80 keV. In addition, in the same manner, a portion where an N-channel TFT is formed is covered with a resist 414 and boron (B) which is a P-type impurity is introduced to form a P-type impurity region 415 (FIG. 6A). In this embodiment, diborane (B₂H₆) is introduced in the range of 30 to 45 keV.

Subsequently, the resist 414 is peeled and a silicon nitride film 416 is formed over the entire surface in 300 nm thick as shown in FIG. 6B. The silicon nitride film 416 can be formed with the use of a plasma CVD method or the like. Further, dry etching is performed using a gas containing bromine to the silicon nitride film 416 as shown in FIG. 6C. In this embodiment, hydrogen bromide, chlorine, and oxygen are mixed as an etching gas to have the flow rate of 100:44:6 and dry etching is performed using an ICP (Inductively Coupled Plasma) apparatus. Note that a pressure is set to 1.6 Pa; a high frequency of ICP, 450 W; and a high frequency of BIAS, 150 W. A high frequency applied to ICP serves to decompose process gas, and a high frequency applied to BIAS serves to accelerate etching species (ion). According to this step, a sidewall 417 is formed on the side surface of the gate electrodes 410 and 411.

Note that the ratio of an etching rate of silicon nitride and silicon oxide achieves 5.04 under this condition. This means that it is possible to perform anisotropic etching to the silicon nitride film with the use of the silicon oxide as a gate insulating film. Thus, it is possible to form the sidewall with the silicon nitride film.

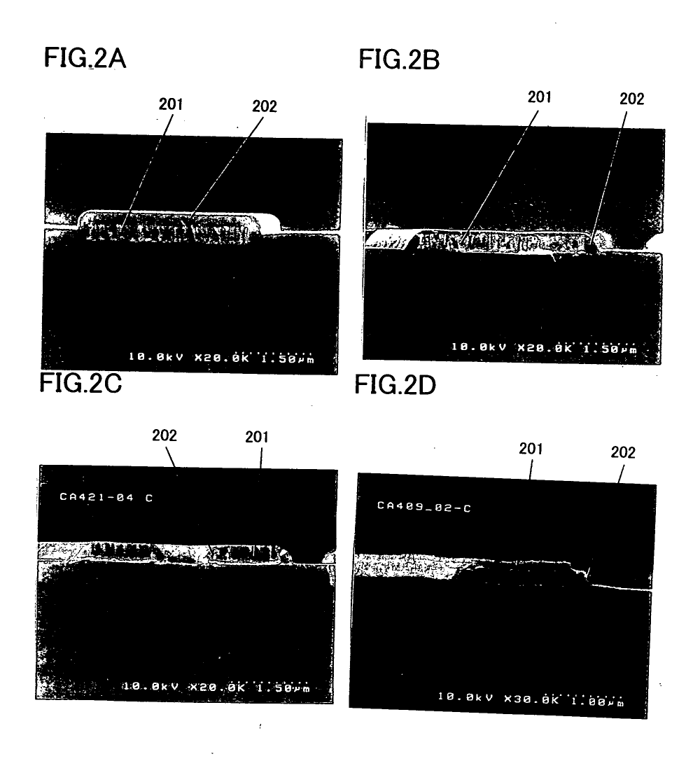

A cross section in the process of performing etching with the use of an HBr gas is shown in FIGS. 2A to 2D and FIGS. 3A to 3D. Note that FIGS. 2A to 2D are views photographed with an electron microscope. In the FIGS. 2A to 2D corresponding to FIGS. 3A to 3D, reference numeral 201 denotes a semiconductor film; and 202, a silicon nitride film, and in FIGS. 3A to 3D, reference numeral 301 denotes a semiconductor film; 302, a silicon nitride film.

FIGS. 2A and 3A are views before an etching process, FIGS. 2B and 3B are views showing 200 seconds passed after starting the etching, and FIGS. 2C and 3C are views showing 240 seconds passed after starting the etching. Note that the etching is to be finished 240 seconds after starting the etching. In addition, FIGS. 2D and 3D are views in which the silicon nitride films 202 and 302 are etched too much so that the semiconductor films 201 and 301 are exposed (260 seconds after starting the etching). Moreover, a width of the sidewall depending on a processing time is shown in Table 1. An average value of the width of the sidewall 240 seconds after starting the process (at the time of finishing the etching) is 236 nm, and the sidewall is formed to have the width almost the same as the thickness of the silicon nitride film before starting the etching.

TABLE 1
sidewall width of silicon nitride [nm]

| processing time | 0 sec | 200 sec | 240 sec |
|---|---|---|---|
| central part of | 210 | 259 | 249 |
| substrate | 240 | 270 | 242 |
| peripheral part of | | 231 | 224 |
| substrate | | 231 | 231 |
| average | 225 | 248 | 236 |

Note that an ICP method is used as a dry etching method in this embodiment; however, the method is not limited thereto. In the same manner, an etching method such as parallel plate type RIE (Reactive Ion Etching), magnetron type RIE, two cycles type RIE, microwave type RIE, ECR (Electron Cyclotron Resonance) plasma etching, or helicon type plasma etching can be used.

Next, as shown in FIG. 6D, a portion to be a P-type TFT is covered with a resist 418 and an ion imparting N-type conductivity is introduced to form an LDD region 419. Note that the ion imparting N-type conductivity with a dose amount larger than the above. In the same manner, a portion to be an N-type TFT is covered with a resist 420 and an ion imparting P-type conductivity is introduced to form an LDD region 421. Similarly, an ion imparting P-type conductivity with a dose amount larger than the above is introduced.

As mentioned above, treatment is performed by laser annealing, lamp annealing, or furnace annealing after completing impurity introduction to activate the introduced impurity and to recover damage of crystallinity due to impurity introduction.

Through the above steps, a P-channel TFT 422 and an N-channel type TFT 423 can be formed over the same substrate.

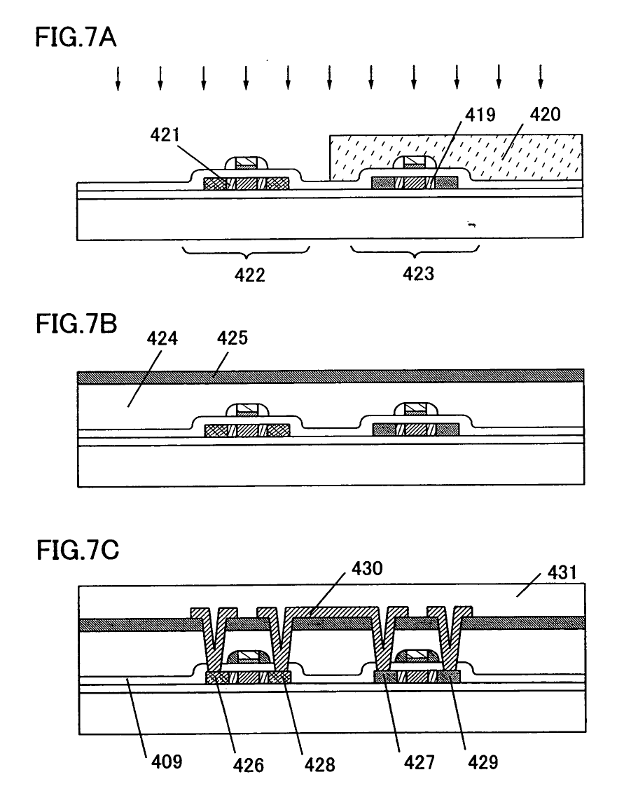

Subsequently, an insulating film 424 is formed as a protective film to protect these TFTs as shown in FIG. 7B. This insulating film 424 is formed in a single layer or multilayer structure of a silicon nitride film or a silicon nitride oxide film in thickness of 100 nm or more and 200 nm or less with the use of a plasma CVD method or a sputtering method. In the case of combining a silicon nitride oxide film and a silicon oxynitride film, these films can be formed continuously by switching gas. In this embodiment, a silicon oxynitride film is formed in 100 nm thick by a plasma CVD method. By providing the insulating film 424, a blocking effect to block the intrusion of various ionic impurities and oxygen and moisture in the air can be obtained.

Next, an insulating film 425 is further formed. Herein, an organic resin film such as polyimide, polyamide, BCB (benzocyclobutene), acrylic, or siloxane (a substance in which a bond of silicon and oxygen represented by —Si—O—Si— (siloxane bond) serves as a basic unit of the structure and silicon is bonded with fluorine, aliphatic hydrocarbon, aromatic hydrocarbon, or the like) coated all over by an SOG (Spin On Glass) method or a spin coating method, an inorganic interlayer insulating film (an insulating film containing silicon such as silicon nitride or silicon oxide), a low-k (low dielectric constant) material, or the like can be used. Since the insulating film 425 is formed mainly for relaxing and flattening the unevenness due to the TFTs formed over the glass substrate, a film being superior in flatness is preferable.

Further, the gate insulating film 409, and the insulating film 424 and the insulating film 425 are patterned by a photolithography method to form contact holes that reach source regions 426 and 427 and drain regions 428 and 429.

Then, a conductive film is formed with a conductive material, and a wiring 430 is formed by patterning the conductive film. Thereafter, a semiconductor device shown in FIG. 7C is completed when an insulating film 431 is formed as a protective film.

A method for manufacturing a semiconductor device of the present invention is not limited to the above manufacturing process of a TFT. In this embodiment, a process for manufacturing a CMOS TFT is shown; however, the method for manufacturing a semiconductor device of the present invention can also be used in forming an N-type TFT, a P-type TFT; or the both over a substrate.

In addition, in a method for manufacturing a semiconductor device according to the present invention, a semiconductor film formed over an insulating substrate such as glass is used. However, without limitation thereto, a semiconductor device of the present invention can also be manufactured using a single-crystal semiconductor substrate in the same manner. As an example of the single-crystal semiconductor substrate, an SOI (Silicon on Insulator) substrate manufactured using a pasting method or an SIMOX (Separation by Implanted Oxygen) method, a silicon wafer, or the like can be used.

### Embodiment 2

In this embodiment, a process of manufacturing a CMOS-type IC using a semiconductor substrate will be explained with reference to drawings.

Note that a semiconductor substrate used in this embodiment refers to a single-crystal silicon substrate or a compound semiconductor substrate, or an SOI (Silicon on Insulator) substrate. An N-type or P-type single-crystal silicon substrate, a GaAs substrate, an InP substrate, a GaN substrate, a SiC substrate, a sapphire substrate, a ZnSe substrate, or the like, can be typically given as the single-crystal silicon substrate or compound semiconductor substrate. A substrate manufactured by a pasting method, a SIMOX (Separation by Implanted Oxygen) method, or the like can be typically given as the SOI substrate. When a semiconductor element is manufactured using an SOI substrate, the adjacent elements can be separated completely; thus, the flowing of leak current can be prevented.

First, a substrate 800 made of single-crystal silicon is prepared, and a first element forming region 802 and a second element forming region 803 are formed by a known LOCOS method or shallow trench isolation method.

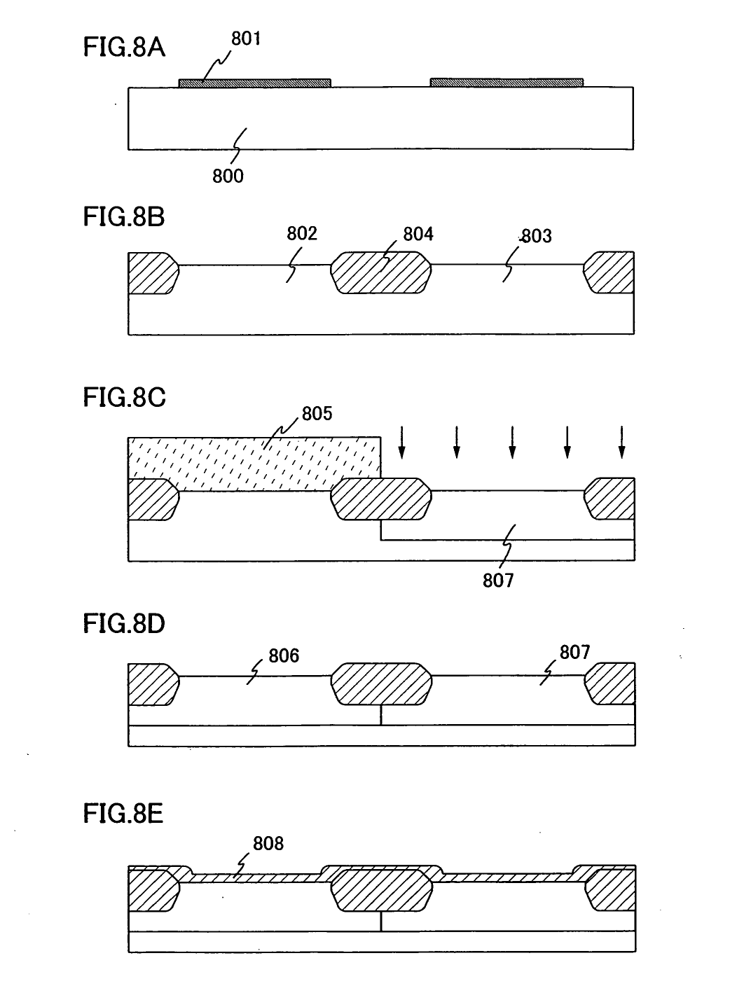

Note that an LOCOS method is used in this embodiment. Specifically, a silicon nitride film 801 is deposited over the single-crystal silicon substrate 800, and the silicon nitride film 601 is removed while remaining a portion thereof which will subsequently become an active region (FIG. 8A).

Then, the silicon nitride film 801 is used as a mask to form a thick silicon oxide film (field oxide film) 804 for separation by a thermal oxidation method. Next, the first element forming region 802 and the second element forming region 803 separated by the field oxide film 804 are formed by removing the silicon nitride film by thermal phosphoric acid (FIG. 8B).

Next; the first element forming region 802 is covered with a resist 805, and a phosphorus (P) ion is implanted into the second element forming region 803 where a P-channel MOS transistor will be formed subsequently, thereby forming a P-type well 807. Similarly, an N-type well 806 is formed in the first element forming region 802 where an N-channel MOS transistor will be formed subsequently (FIG. 8C).

Then, the resist 805 is peeled to expose surfaces of the first element forming region 802 and the second element forming region 803 (FIG. 8D). Thereafter, a thin gate insulating film 808 is formed with a material of silicon oxide on these surfaces by a thermal oxidation method (FIG. 8E).

The gate insulating film 808 may be formed by a plasma CVD method, a sputtering method, or the like. For example, the gate insulating film 808 may be formed with a multilayer film in which a silicon oxide film in 5 nm thick which is obtained by a thermal oxidation method and a silicon oxynitride film in thickness of 10 nm or more and 15 nm or less which is obtained by a CVD method are stacked. These films can also be formed continuously by switching gas.

Note that the gate insulating film 808 is not limited to the above materials. Additionally, the following can be used: (1) a silicon oxide film, a silicon oxide film containing nitrogen (SiON), a silicon nitride film containing oxygen (SiNO), a silicon nitride film, or a multilayer film of these, or (2) a high dielectric constant substance material (also referred to as a high-k material) such as tantalum nitride, hafnium oxide (HfO₂), nitrided hafnium silicon oxide (HfSiON), zirconium oxide (ZrO₂), or aluminum oxide (Al₂O₃), or rare-earth oxide such as lanthanum oxide (La₂O₂).

Subsequently, a conductive film is formed over the gate insulating film 808 and patterned desirably to form gate electrodes 809 and 810 in the following manner. First, the material of the conductive film formed over the gate insulating film 808 may be a film having conductivity. In this embodiment, a film in which TaN (tantalum nitride) is formed in 30 nm thick and further W (tungsten) is formed in 370 nm thick is used. A resist mask for patterning this conductive film is formed, and the gate electrodes 809 and 810 are formed by patterning the conductive film with this resist mask.

Note that, without limitation thereto, a conductive film formed by stacking Mo (molybdenum), Al (aluminum), and Mo sequentially or a conductive film formed by stacking Ti (titanium), Al, and Ti sequentially may also be used. In addition, one or more elements of gold (Au), silver (Ag), copper (Cu), platinum (Pt), aluminum (Al), molybdenum (Mo), tungsten (W), and titanium (Ti), or an alloy material or a compound material containing such an element as the main component can be used. Further, a multilayer film of these materials may also be used. When the gate electrodes 809 and 810 are formed using a material made from the above metal in the case of particularly forming the gate insulating film 808 with the use of the above high dielectric constant substance (high-k material), the depletion of the gate electrodes 809 and 810 can be reduced and a large amount of current can flow so that lower power consumption of a semiconductor element can be achieved.

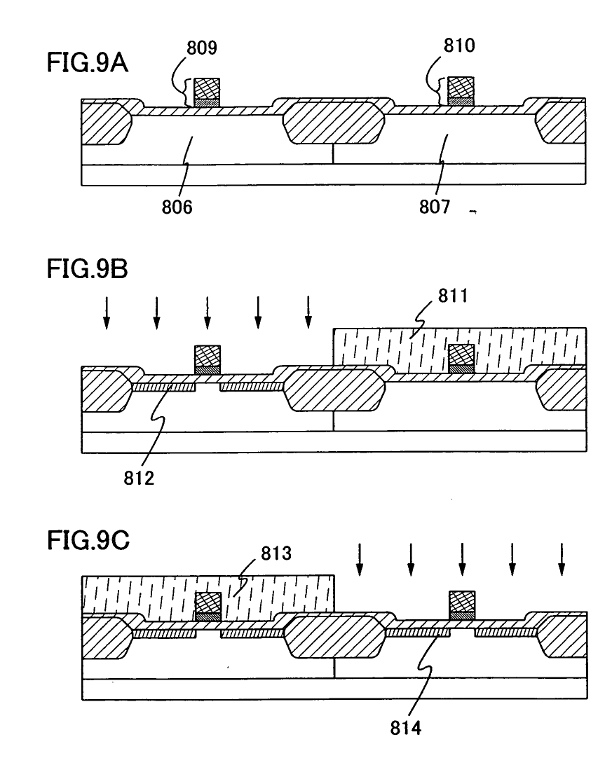

Next, as shown in FIG. 9B, a portion where a P-channel TFT is formed is covered with a resist 811 and arsenic (As) or phosphorus (P) which is an N-type impurity is lightly introduced to form an N-type impurity region 812. Subsequently, the resist 811 is removed, and a portion where an N-channel TFT is formed is covered with a resist 813 and boron (B) which is a P-type impurity is lightly introduced to form a P-type impurity region 814 (FIG. 9C).

Here, an element having large mass number such as germanium (Ge) or an element belonging to Group 0 (Ar, Kr, Xe, Rn, or the like) may be implanted at the same time as implanting the impurity element, so that a single-crystal lattice is broken. At this time, the implantation speed is decreased to make a semiconductor film amorphous approximately 20 nm in depth. The order of the impurity introduction and the implantation of the element having large mass number are not limited. Either one may be conducted first, or they may be conducted at the same time.

In the silicon substrate 800, atoms are arranged in order. In particular, in a <100>plane or a <111>plane, a phenomenon in which the introduced impurities pass through a space between crystals to penetrate deep in the substrate occurs (channeling phenomenon). Consequently, the impurities are implanted in such a way that a direction in which the impurities are introduced is tilted to the silicon substrate 800, which makes it possible to decrease the space between the atoms. Therefore, the introduced impurities are likely to stop at the vicinity of the surface of the crystals.

In addition, since an uneven portion exists around the gate electrodes 809 and 810, a region where the impurities and the element having large mass number are not introduced is likely to be formed (referred to as a shadow effect). In order to prevent the shadow effect, the impurities may be implanted while rotating the silicon substrate 800 continuously or the impurity introduction and the rotation of the substrate may be performed alternately. It is more preferable to implant the impurities and the element having large mass number in such a way that the implantation direction of the impurity and the element having large mass number is oblique relative to the silicon substrate 800 and the silicon substrate 800 is rotated, because the channeling phenomenon and the shadow effect can be prevented at the same time.

Further, a first activation process is performed to activate the implanted impurity portion and recover a crystal defect of a semiconductor film caused by implanting the impurities. Note that this activation process can be performed using a known method such as an RTA method, a laser annealing method, or the like. Note that, since impurities are lightly introduced here, only a portion shallow from the surface can be preferably activated with the use of a laser with a small pulse width (1 femtosecond or more and 10 picoseconds or less).

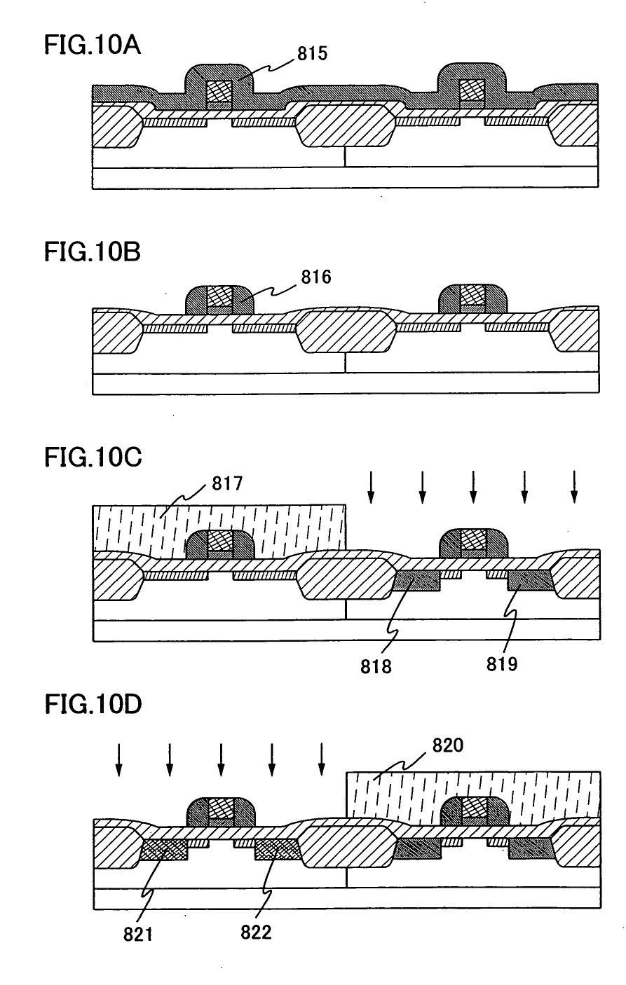

Then, the resist 813 is peeled and a silicon nitride film 815 is formed over the entire surface in 300 nm thick as shown in FIG. 10A. The silicon nitride film 815 can be formed with the use of a plasma CVD method or the like. Further, dry etching is performed using a gas mainly containing hydrogen bromide (HBr) to the silicon nitride film 815 to form a sidewall 816 as shown in FIG. 10B. In this embodiment, hydrogen bromide, chlorine, and oxygen are mixed as an etching gas to have the flow rate of 100:44:6 and dry etching is performed using an ICP (Inductively Coupled Plasma) apparatus. According to this process, the sidewall made of silicon nitride is preferably formed on the side surface of the gate electrodes 809 and 810. The width of this sidewall has approximately the same length as that of the film thickness of the silicon nitride film 815.

Note that an ICP method is used as a dry etching method in this embodiment; however, the method is not limited thereto. In the same manner, an etching method such as parallel plate type RIE (Reactive Ion Etching), magnetron type RIE, two cycles type RIE, microwave type RIE, ECR (Electron Cyclotron Resonance) plasma etching, or helicon type plasma etching can be used.

Subsequently, ion implantation is performed into the silicon substrate in order to form a source region and a drain region. This is the case of forming a CMOS; therefore, as shown in FIG. 10C, the first element forming region 802 for forming an N-channel TFT is covered with a resist 817 and boron (B) which is a P-type impurity is injected into the second element forming region 803, thereby forming a source region 818 and a drain region 819. In the same manner, the second element forming region 803 for forming a P-channel TFT is covered with a resist 820 and phosphorus (P) or arsenic (As) which is an N-type impurity is implanted into the first element forming region 802, thereby forming a source region 821 and a drain region 822 (FIG. 10D).

Next, a second activation process is performed to activate the implanted impurities and recover a crystal defect of the silicon substrate caused by the ion implantation. This activation process can be performed using a known method such as an RTA method, a laser annealing method, or the like.

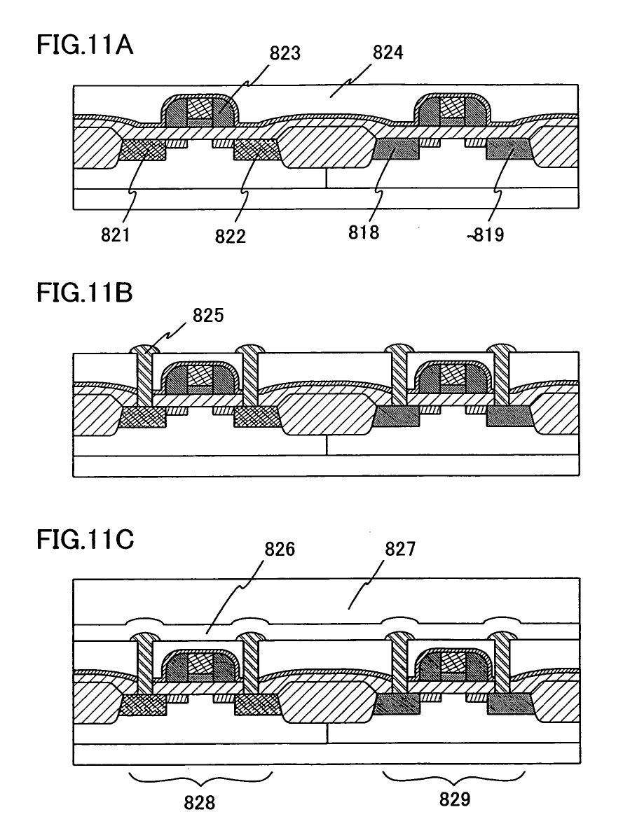

Then, an interlayer insulating film, a wiring, and the like are formed after the activation. As shown in FIG. 11A, a first interlayer insulating film 823 is formed with a silicon oxide film, a silicon oxynitride film, or the like by a plasma CVD method or a low-pressure CVD method in thickness of 100 nm or more and 2000 nm or less. Further, a second interlayer insulating film 824 is formed with phosphosilicate glass (PSG), borosilicate glass (BSG), or borophosphosilicate glass (PBSG) over the first interlayer insulating film 823. The second interlayer insulating film 824 is formed by a spin coating method or a normal-pressure CVD method in order to increase the flatness.

Subsequently, as shown in FIG. 11B, contact holes (openings) which each reach the source region and the drain region of the TFT are formed in the first interlayer insulating film 823 and the second interlayer insulating film 824, and then a wiring 825 is connected to the source electrodes 818 and 821 and the drain electrodes 819 and 822. The source electrodes 818 and 821 and the drain electrodes 819 and 822 can be formed with aluminum (Al) which is usually used as a low-resistant material, a multilayer film of aluminum and titanium (Ti), or the like.

Although not shown here, other contact holes which reach the gate electrodes 809 and 810 are also formed in the first interlayer insulating film 823 and the second interlayer insulating film 824 at the same time as forming the contact holes for forming the source electrodes 818 and 821 and the drain electrodes 819 and 822, so that an electrode which electrically connects to a wiring provided over the first interlayer insulating film 823 is provided.

Finally, a passivation film 826 and a third interlayer insulating film 827 are formed as shown in FIG. 11C. In FIG. 11C, an N-channel TET 828 is on the left side and a P-channel TFT 829 is on the right side.

The passivation film 826 is formed with a silicon nitride film, a silicon oxide film, or a silicon nitride oxide film by a plasma CVD method. Further, the third interlayer insulating film 827 is formed with an organic resin material in thickness of 1 μm or more and 2 μm or less. The organic resin material to be used here can be polyimide, polyamide, acrylic, benzocyclobutene (BCB), or the like. The advantages in using the organic resin film are such that the film can be easily formed, a parasitic capacitance can be decreased because a specific dielectric constant is low, or the film can be easily flattened. An organic resin film besides the above films may also be used.

Note that this embodiment can be combined with embodiment mode and other embodiments.

### Embodiment 3

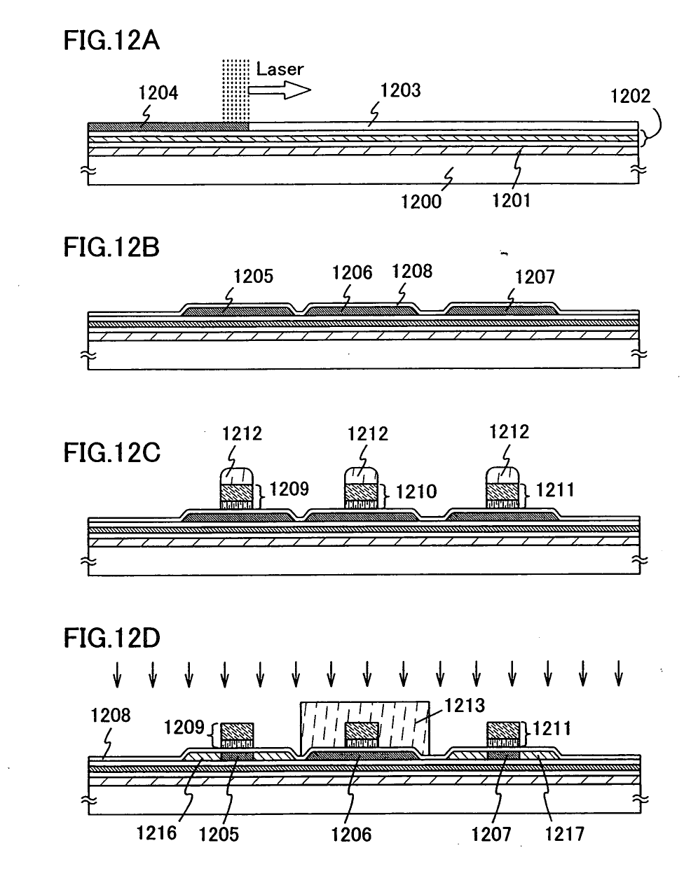

Here, a process of manufacturing a thin film integrated circuit or a non-contact thin film integrated circuit device (also referred to as a wireless IC tag or an RFID (Radio Frequency Identification)) is shown as an example of a semiconductor device manufactured according to the present invention, with reference to FIGS. 12A to 12D, FIGS. 13A to 13D, FIGS. 14A to 14C, FIGS. 15A to 15C, and FIGS. 16A and 16B.

Although an example of using electrically isolated TFTs as a semiconductor element used for an integrated circuit of a wireless IC tag is shown below, the semiconductor element used for the integrated circuit of the wireless IC tag is not limited to TFTs and any kinds of elements can be used. For example, besides TFTs, a storage element, a diode, a photoelectric conversion element, a resistor element, a coil, a capacitor element, an inductor, or the like is typically given.

First, a peeling layer 1201 is formed over a glass substrate (a first substrate) 1200 by a sputtering method as shown in FIG. 12A. The peeling layer 1201 can be formed by a sputtering method, a low-pressure CVD method, a plasma CVD method, or the like. In this embodiment, amorphous silicon is formed in approximately 50 nm thick by a low-pressure CVD method and used as the peeling layer 1201. Note that the peeling layer 1201 is not limited to silicon and may be formed with a material which can be selectively etched away (For example, tungsten (W), molybdenum (Mo), titanium (Ti), tantalum (Ta), niobium (Nb), nickel (Ni), cobalt (Co), zirconium (Zr), zinc (Zn), ruthenium (Rh), rhodium (Rh), palladium (Pd), osmium (Os), iridium (Ir), or the like). A film made of a single element of the above, an alloy material containing the above elements as the main component, or a compound of the above elements is formed in a single layer or a multilayer structure. The film thickness of the peeling layer 1201 is desirably 50 nm or more and 60 nm or less.

In addition, in the case of forming the peeling layer 1201 to have a two-layered structure of a metal film and a metal oxide film, the metal film and the metal oxide film each can be provided by a sputtering method or a plasma CVD method. With the use a method besides this, plasma treatment or heat treatment is performed under an oxygen atmosphere after forming the above metal film so that oxide of the metal can be provided over the surface of the metal film. Note that plasma treatment also includes high-density plasma treatment.

High-density plasma is generated by using a microwave of 2.45 GHz, for example. High-density plasma the characteristic of which is low electron temperature has low kinetic energy of active species. Therefore, it is possible to form a film having less plasma damage and defect compared with the conventional plasma treatment.

Moreover, in addition to the metal oxide film, metal nitride, metal nitride containing oxygen, or metal oxide containing nitrogen may be used as the peeling layer 1201. In the case of forming metal nitride, plasma treatment or heat treatment may be performed to a metal film under a nitrogen atmosphere. In addition, in the case of forming metal nitride containing oxygen or metal nitride containing nitrogen, plasma treatment or heat treatment may be performed to a metal film under an atmosphere containing nitrogen and oxygen. The type of film to be deposited differs depending on the flow rate of gas to be used.

When the peeling layer 1201 is formed, oxide, nitride, or nitride oxide is formed over the surface. Such a compound has a high reaction rate with an etching gas, particularly chlorine trifluoride (ClF₃); thus, peeling can be performed briefly and in a short time. In other words, it is possible to perform peeling as long as any one of metal, metal oxide, metal nitride, and nitride oxide of metal is removed by etching gas.

In addition, when oxide, nitride, or nitride oxide is formed over the surface of the peeling layer 1201, chemical change occurs. For example, in the case where an oxide film having tungsten (W) is formed, tungsten oxide (WOₓ(x=2 to 3)) is changed in valence. Consequently, the peeling layer 1201 becomes to be easily peeled by a physical means. Oxide, nitride, or nitride oxide can be removed much easily and in a shorter time by combining a chemical means and a physical means.

Subsequently, a base insulating film 1202 is formed over the peeling layer 1201. The base insulating film 1202 is provided to prevent an alkali metal such as Na or alkaline-earth metal contained in the first substrate from diffusing into a semiconductor film and adversely affecting the characteristic of a semiconductor element. In addition, the base insulating film 1202 serves to protect semiconductor elements in the subsequent step of peeling the semiconductor elements. The base insulating film 1202 may have a single layer or multilayer structure stacking a plurality of insulating films. Therefore, the base insulating film 1202 is formed with an insulating film which can suppress the diffusion of alkali metal or alkaline-earth metal into the semiconductor film, such as silicon oxide, silicon nitride, silicon oxide containing nitrogen (SiON), or silicon nitride containing oxygen (SiNO).

Next, a semiconductor film 1203 is formed over the base insulating film 1202. It is desirable to form the semiconductor film 1203 without being exposed to the air after forming the base insulating film 1202. The thickness of the semiconductor film 1203 is set to 20 nm or more and 200 nm or less (desirably 40 nm or more and 170 nm or less, more desirably 50 nm or more and 150 nm or less)

Then, the semiconductor film 1203 is crystallized by being irradiated with a laser beam. Thus, a crystalline semiconductor film 1204 is formed by irradiating the semiconductor film 1203 with a laser beam. Note that, in order to improve the crystallinity, laser irradiation can also be performed after coating a solution containing metal such as nickel all over the semiconductor film 1203. In addition, instead of laser beam irradiation, an annealing furnace using a electrothermal furnace, a rapid thermal annealing method (an LRTA method) using a lamp such as a halogen lamp, a metal halide lamp, a xenon arc lamp, a carbon arc lamp, a high-pressure sodium lamp, or a high-pressure mercury lamp, or a thermal annealing method using heated gas (a GRTA method) may also be employed.

Then, the crystalline semiconductor film 1204 is patterned to form island-shaped semiconductor films 1205 to 1207 as shown in FIG. 12B. Thereafter, a gate insulating film 1208 is formed. The gate insulating film 1208 can be formed with a film containing silicon nitride, silicon oxide, silicon oxide containing nitrogen, or silicon nitride containing oxygen in a single layer or multilayer structure by a plasma CVD method, a sputtering method, or the like.

After forming the gate insulating film 1208, heat treatment may be performed at temperatures of 300° C. or more and 450° C. or less for an hour or more and 12 hours or less in an atmosphere containing hydrogen for 3% or more and 100% less to hydrogenate the island-shaped semiconductor films 1205 to 1207. In addition, plasma hydrogenation (using hydrogen excited in plasma) may be performed as another means of hydrogenation.

Subsequently, as shown in FIG. 12C, gate electrodes 1209 to 1211 are formed. Here, the gate electrodes 1209 to 1211 are formed by etching a TaN (tantalum nitride) film and W (tungsten) film formed by a sputtering method or a plasma CVD method by using a resist 1212 as a mask. Of course, the conductive material, structure, and manufacturing method of the gate electrodes 1209 to 1211 are not limited to these and can be appropriately selected. For example, a multilayer structure of a Si film and a NiSi (nickel silicide) film doped with impurities imparting N-type conductivity or a multilayer structure of silicon and tungsten may also be used. In addition, in forming conductive films constituting the gate electrodes, the conductive films may be deposited continuously further in a single layer using various conductive materials. In the case of forming the gate electrodes and an antenna simultaneously, the material may be selected in consideration of those functions.

Moreover, a mask made of SiOₓ or the like may be used instead of the resist mask. In this case, a step of forming a mask of SiOₓ, SiON, or the like (referred to as a hard mask) by patterning the material is added. However, since the film decrease of the mask at the etching is less than that of the resist, the gate electrodes 1209 to 1211 having a desired width can be formed.

Next, as shown in FIG. 12D, the island-shaped semiconductor film 1206 to be a P-channel TFT is covered with a resist 1213 and the island-shaped semiconductor films 1205 and 1207 are doped with an impurity element imparting N-type conductivity (typically P (phosphorus) or Ar (arsenic)) at low concentration by using the gate electrodes 1209 and 1211 as masks. In this doping step, doping is performed through the gate insulating film 1208, and a pair of low-concentration impurity regions 1216 and 1217 is formed in the island-shaped semiconductor films 1205 and 1207. Note that this doping step may be performed without covering the island-shaped semiconductor film 1206 to be the P-channel TFT with the resist.

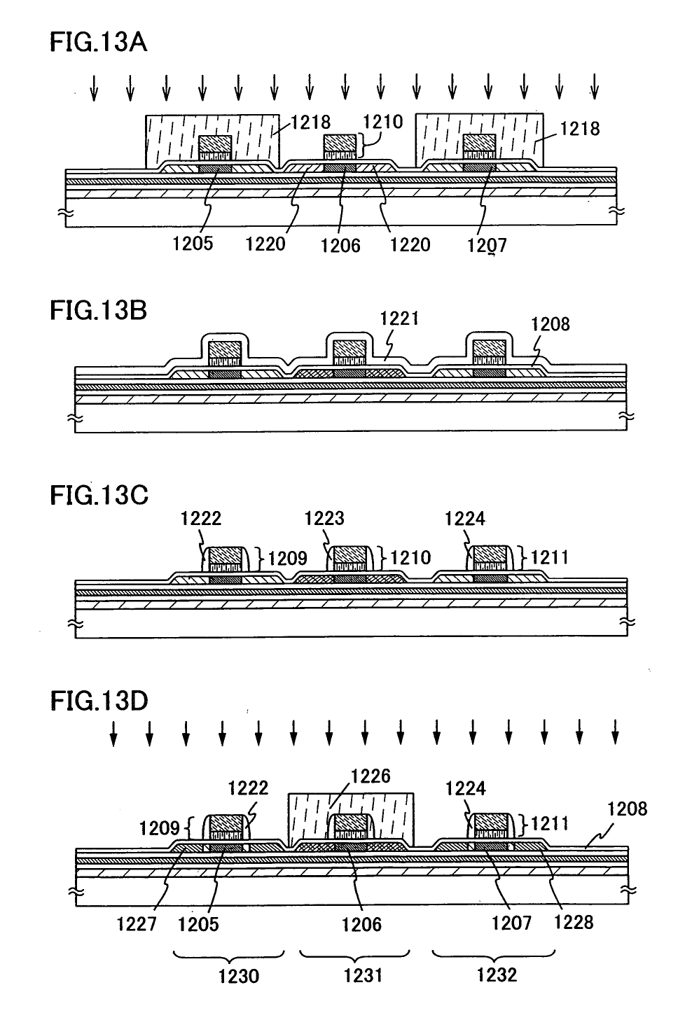

Then, after removing the resist 1213 by ashing or the like, a resist 1218 is newly formed to cover the island-shaped semiconductor films 1205 and 1207 to be N-channel TFTs as shown in FIG. 13A, and then the island-shaped semiconductor film 1206 is doped with an impurity element imparting P-type conductivity (typically B (boron)) at high concentration by using the gate electrode 1210 as a mask. In this doping step, the doping is performed through the gate insulating film 1208 to form a pair of P-type high-concentration impurity regions 1220 in the island-shaped semiconductor film 1206.

Subsequently, as shown in FIG. 13B, after removing the resist 1218 by ashing or the like, a silicon nitride film 1221 is formed so as to cover the gate insulating film 1208 and the gate electrodes 1209 to 1211. The silicon nitride film 1221 can be formed using a plasma CVD method or the like.

Thereafter, dry etching is performed using a gas mainly containing hydrogen bromide (HBr) to the silicon nitride film 1221 to form sidewalls 1222 to 1224 as shown in FIG. 13C. As well as in other embodiments, hydrogen bromide, chlorine, and oxygen are mixed as an etching gas to have the flow rate of 100:44:6 and dry etching is performed using an ICP (Inductively Coupled Plasma) apparatus. A pressure is set to 1.6 Pa; a high frequency of ICP, 450 W; and a high frequency of BIAS, 150 W.

Note that an ICP method is used as a dry etching method in this embodiment; however, the method is not limited thereto. In the same manner, an etching method such as parallel plate type RIE (Reactive Ion Etching), magnetron type RIE, two cycles type RIE, microwave type RIE, ECR (Electron Cyclotron Resonance) plasma etching, or helicon type plasma etching can be used.

Next, a resist 1226 is newly formed to cover the island-shaped semiconductor film 1206 to be the P-channel TFT and an impurity element imparting N-type conductivity (typically P or As) is added at high concentration by using the gate electrodes 1209 and 1211 and the sidewalls 1222 and 1224 as masks as shown in FIG. 13D. According to this doping step, doping is performed through the gate insulating film 1208 and a pair of N-type high-concentration impurity regions 1227 and 1228 is formed in the island-shaped semiconductor films 1205 and 1207.

Then, after removing the resist 1226 by ashing or the like, the impurity regions may be thermally activated. For example, after forming a SiON film in 50 nm thick, heat treatment may be performed at 550° C. for four hours under a nitrogen atmosphere. In addition, when another heat treatment is performed at 410° C. for one hour under a nitrogen atmosphere after forming a SiNₓ film containing hydrogen in 100 nm thick, a defect in a poly-crystalline semiconductor film can be improved. This is, for example, to terminate a dangling bond in the poly-crystalline semiconductor film and referred to as a hydrogenation step or the like.

Through the above series of steps, an N-channel TFT 1230, a P-channel TFT 1231, and an N-channel TFT 1232 are formed. In the above manufacturing process, a TFT having a channel length of 0.2 μm or more and 2 μm or less can be formed by appropriately changing a condition of an etch back method to adjust the size of the sidewall.

Further, a passivation film may be formed to protect the TFTs 1230 to 1232.

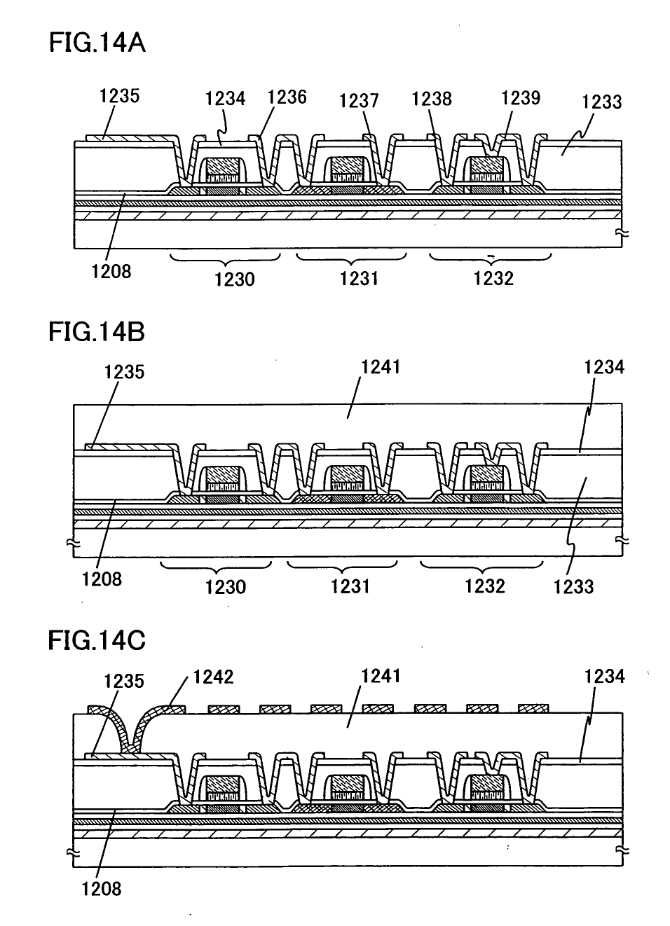

Subsequently, a first interlayer insulating film 1233 is formed so as to cover the TFTs 1230 to 1232 as shown in FIG. 14A.

Further, a second interlayer insulating film 1234 is formed over the first interlayer insulating film 1233. A filler may be mixed into the first interlayer insulating film 1233 or the second interlayer insulating film 1234 in order to prevent the first interlayer insulating film 1233 or the second interlayer insulating film 1234 from peeling and breaking due to the stress caused by the difference of the coefficient of thermal expansion between the conductive material for constituting the wiring to be formed afterward and the first interlayer insulating film 1233 or the second interlayer insulating film 1234.

Next, contact holes are formed in the first interlayer insulating film 1233, the second interlayer insulating film 1234, and the gate insulating film 1208, and then wirings 1235 to 1239 to connect with the TFTs 1230 to 1232 are formed. Note that the wirings 1235 and 1236 are connected to the high-concentration impurity region 1227 of the N-channel TFT 1230, the wirings 1236 and 1237 are connected to the high-concentration impurity region 1220 of the P-channel TFT 1231, and the wirings 1238 and 1239 are connected to the high-concentration impurity region 1228 of the N-channel TFT 1232, respectively. Further, the wiring 1239 is also connected to the gate electrode 1211 of the N-channel TFT 1232. The N-channel TFT 1232 can be used as a memory element of a random ROM.

Then, as shown in FIG. 14B, a third interlayer insulating film 1241 is formed over the second interlayer insulating film 1234 so as to cover the wirings 1235 to 1239. Note that the third interlayer insulating film 1241 can be formed with the same material as the first interlayer insulating film 1233.

Subsequently, an antenna 1242 is formed over the third interlayer insulating film 1241. First, an opening is formed in the third interlayer insulating film 1241 so that any one of the wirings 1235 to 1239 is partially exposed. In this embodiment, an opening is formed so that the wring 1235 is exposed. Subsequently, the antenna 1242 is formed. The antenna 1242 can be formed with a conductive material having one or a plurality of metals or a metal compound of Ag, Au, Cu, Pd, Cr, Mo, Ti, Ta, W, Al, Fe, Co, Zn, Sn, and Ni. Then, the antenna 1242 is connected to the wiring 1235.

Although the antenna 1242 is directly connected to the wiring 1235 in FIG. 14C, a wireless IC tag of the present invention is not limited to this structure. For example, the antenna 1242 may be connected electrically to the wiring 1235 by using a wiring separately formed.

The antenna 1242 can be formed by a printing method, a photolithography method, a vapor deposition method, a droplet discharging method, or the like. In FIG. 14C, the antenna 1242 is formed with a single conductive film. However, the antenna 1242 can be formed by stacking a plurality of conductive films. For example, the antenna 1242 may be formed with Ni wiring coated with Cu by electroless plating.

Note that a droplet discharging method is a method for forming a predetermined pattern by discharging a droplet including a predetermined composition from a small hole. An ink-jet method and the like are included in its category. On the other hand, a printing method includes a screen printing method, an offset printing method, and the like. When a printing method or a droplet discharging method is employed, the antenna 1242 can be formed without using a mask for light exposure. In addition, when a printing method or a droplet discharging method is employed, unlike a photolithography method, the material that will be etched away can be saved. Moreover, since an expensive mask for the light exposure is not necessary, the cost for manufacturing the wireless IC tag can be reduced.

In the case of using a droplet discharging method or various kinds of printing methods, for example, conductive particles of Cu coated with Ag can be used. Note that, when the antenna 1242 is formed by a droplet discharging method, it is desirable to perform a process for improving the adhesiveness of the antenna 1242 to the surface of the third interlayer insulating film 1241.

There are several methods which can improve the adhesiveness. Specifically, one is that a metal or a metal compound that can improve the adhesiveness of a conductive film or an insulating film due to a catalytic action is attached to the surface of the third interlayer insulting film 1241. Another is that an organic insulating film, a metal, or a metal compound having high adhesiveness to a conductive film or an insulating film to be formed is attached to the surface of the third interlayer insulating film 1241. The other is that a plasma process is performed to the surface of the third interlayer insulating film 1241 under an atmospheric pressure or a reduced pressure so that the surface thereof is modified.

When the metal or the metal compound attached to the third interlayer insulating film 1241 is conductive, the sheet resistance is controlled so that the normal operation of the antenna is not interrupted. Specifically, the average thickness of the conductive metal or a metal compound may be controlled to be 1 nm or more and 10 nm or less. In addition, the metal or the metal compound may be insulated partially or wholly by oxidization. Alternatively, the metal or the metal compound attached to the region in which the adhesiveness is not necessary may be removed selectively by etching. The metal or the metal compound may be attached selectively only to a particular region by a droplet discharging method, a printing method, or a sol-gel method instead of attaching the metal or the metal compound over the substrate in advance. The metal or the metal compound does not need to be a totally continuous film over the surface of the third interlayer insulating film 1241 but may be dispersed to some extent.

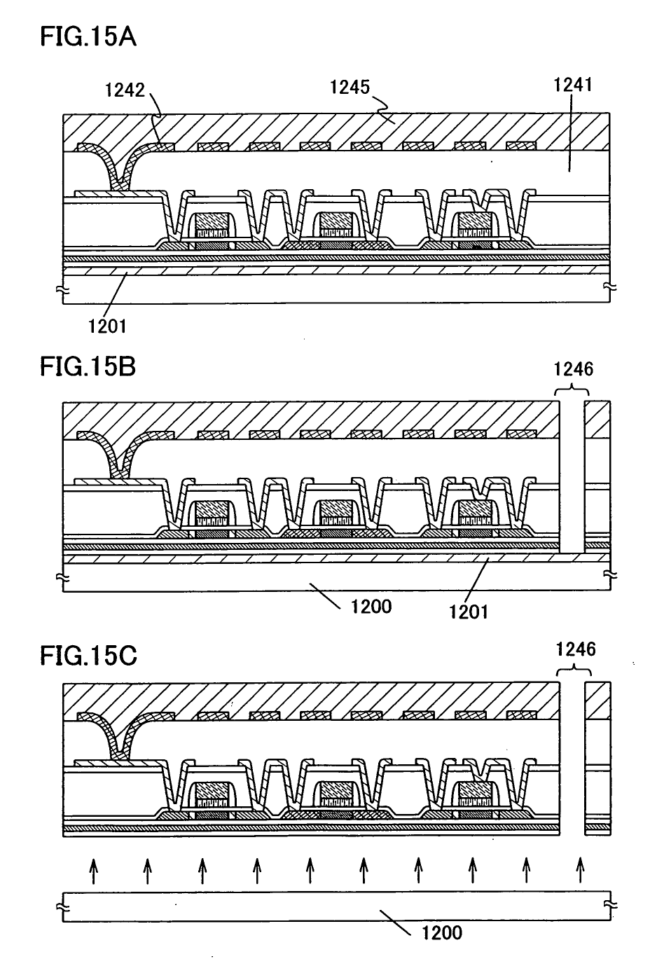

Then, as shown in FIG. 15A, after forming the antenna 1242, a protective layer 1245 is formed over the third interlayer insulating film 1241 so as to cover the antenna 1242. The protective layer 1245 is formed with a material which can protect the antenna 1242 when the peeling layer 1201 is etched away afterward. For example, the protective layer 1245 can be formed by coating an epoxy resin, acrylate resin, or silicon resin being able to dissolve in water or alcohols all over the entire surface.

Subsequently, as shown in FIG. 15B, a groove 1246 is formed in order to divide the wireless IC tags. The groove 1246 may have the depth of such a degree that the peeling layer 1201 is exposed. The groove 1246 can be formed by dicing or scribing the layer. Note that the groove 1246 is not necessarily formed when it is not required to divide the wireless IC tags formed over the first substrate 1200.

Next, as shown in FIG. 15C, the peeling layer 1201 is removed by etching. Here, halogen fluoride is introduced as an etching gas from the groove 1246. For example, ClF₃ (chlorine trifluoride) is used under a condition where a temperature is 350° C., a flow rate is 300 sccm, a barometric pressure is 798 Pa, and a process time is 3 hours. In addition, nitrogen may be mixed into the ClF₃ gas. The peeling layer 1201 can be selectively etched by using halogen fluoride such as ClF₃ so that the TFTs 1230 to 1232 can be peeled from the first substrate 1200. The halogen fluoride may be gas or liquid.

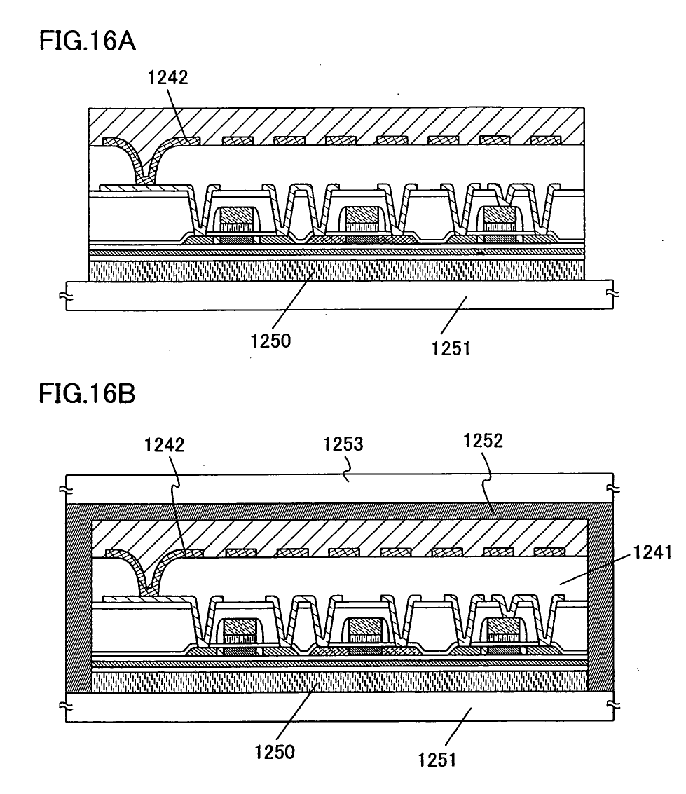

Then, as shown in FIG. 16A, the peeled TFTs 1230 to 1232 and the antenna 1242 are attached to a second substrate 1251 by using an adhesive agent 1250. The adhesive agent 1250 is formed with a material that can attach the second substrate 1251 and the base film 1202. The adhesive agent 1250 may be, for example, a reactive-curing type, a thermal-curing type, a photo-curing type such as a UV-curing type, or an anaerobic type.

Note that the second substrate 1251 can be formed with a flexible organic material such as paper or plastic.

As shown in FIG. 16B, after removing the protective layer 1245, an adhesive agent 1252 is coated over the third interlayer insulating film 1241 so as to cover the antenna 1242, and then a cover member 1253 is attached. A flexible organic material such as paper or plastic can be used for the cover member 1253 as the case of the second substrate 1251. The thickness of the adhesive agent 1252 may be 10 nm or more and 200 μm or less, for example.

In addition, the adhesive agent 1252 is formed with a material being able to attach the cover member 1253 to the third interlayer insulating film 1241 and to the antenna 1242. The adhesive agent 1252 can be, for example, a reactive-curing type, a thermal-curing type, a photo-curing type such as a UV-curing type, or an anaerobic type.

Through each of the above steps, a wireless IC tag is completed. According to the above manufacturing method, an extremely thin integrated circuit having the total thickness of 0.3 μm or more and 3 μm or less, typically approximately 2 μm, can be formed between the second substrate 1251 and the cover member 1253.

Note that the thickness of the integrated circuit includes not only the thickness of the semiconductor element itself but also the thicknesses of the various insulating films and interlayer insulating films formed between the adhesive agent 1250 and the adhesive agent 1252. In addition, the integrated circuit in the wireless IC tag can be made to have a length of 5 mm or less on a side (25 mm² or less), more preferably approximately 0.3 mm (0.09 mm²) to 4 mm (16 mm²) on a side.

Note that this embodiment shows the method in which the peeling layer is provided between the first substrate 1200 having high heat resistance and the integrated circuit, and the substrate and the integrated circuit are separated by removing the peeling layer through the etching. However, a method for manufacturing a wireless IC tag of the present invention is not limited to this structure. For example, a metal oxide film may be provided between the integrated circuit and the substrate having high heat resistance, and the metal oxide film may be weakened by crystallization so that the integrated circuit is peeled. Alternatively, the peeling layer formed with an amorphous semiconductor film containing hydrogen may be provided between the integrated circuit and the substrate having high heat resistance, and the peeling layer may be removed by the laser irradiation. Alternatively, the integrated circuit may be peeled from the substrate by mechanically removing the substrate having high heat resistance with the integrated circuit formed thereover or by removing the substrate by etching with the use of solution or gas.

Although this embodiment explains the example for forming the antenna over the same substrate as the integrated circuit, the present invention is not limited to this structure. An antenna formed over a different substrate and the integrated circuit may be attached afterward so that they are connected electrically.

The frequency of an electric wave usually applied in RFID (Radio Frequency Identification) is mostly 13.56 MHz or 2.45 GHz, and it is important to form a wireless IC tag so that the electric waves of these frequencies can be detected in order to enhance the versatility.

The wireless IC tag of this embodiment has advantages that the electric wave is hard to be blocked compared to an RFID formed using a semiconductor substrate and that attenuation of a signal due to the block of the electric wave can be suppressed. Thus, since a semiconductor substrate is not necessary in this embodiment, the cost for manufacturing the wireless IC tag can be reduced drastically.

Although this embodiment explains the example in which the peeled integrated circuit is pasted to the flexible substrate, the present invention is not limited to this structure. For example, when the substrate can resist the heat process in the manufacturing steps of the integrated circuit like a glass substrate, the integrated circuit over the glass substrate is not necessarily peeled.

In addition, this embodiment can be arbitrarily combined with the embodiment mode or other embodiments.

### Embodiment 4

A TFT manufactured according to the present invention can be used for a thin film integrated circuit or a non-contact thin film integrated circuit device (also referred to as a wireless IC tag or an RFID (Radio Frequency Identification)). By using the manufacturing method shown in other embodiment, the thin film integrated circuit and the non-contact thin film integrated circuit can be used as a tag or a memory.

There can be less dimensional change in width of a sidewall when a silicon nitride film is etched because high anisotropy can be obtained according to the present invention compared with the conventional technique. Further, it is possible to form an LDD region preferably in accordance with this sidewall. Thus, a wireless IC tag using a TFT formed according to the present invention is preferable in quality without variation.

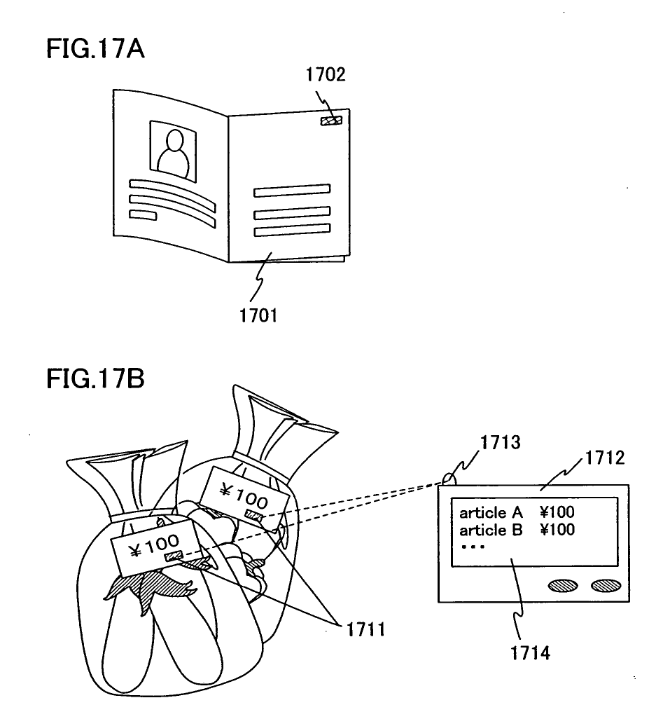

FIG. 17A shows a passport 1701 to which a wireless IC tag 1702 is attached. The wireless IC tag 1702 may be embedded in the passport 1701. In the same way, the wireless IC tag can be attached to or embedded in a driver's license, a credit card, a banknote, a coin, a certificate, a merchandise coupon, a ticket, a traveler's check (T/C), a health insurance card, a residence certificate, a family register, or the like. In this case, only the information showing that this product is a real one is inputted into the wireless IC tag, and access authority is set so that the information is not read out or written in illegally. This can be achieved by using the TFT formed according to the present invention. Real products can be distinguished from forged ones by thus using the TFT according to the present invention as a tag.

Besides, the wireless IC tag can also be used as a memory. FIG. 17B shows an example of using a wireless IC tag 1711 embedded in a label attached to a package of vegetables. The wireless IC tag 1711 may be attached to or embedded in the package itself. In the wireless IC tag 1711, a production area, a producer, a manufacturing date, a process at the production such as a process method, a circulation process of a product, a price, quantity, an intended purpose, a shape, weight, an expiry date, or other identification information can be stored. The information from the wireless IC tag 1711 can be received by an antenna portion 1713 of a wireless reader 1712, and read out and displayed in a display portion 1714 of the reader 1712. Thus, wholesalers, retailers, and consumers can know such information easily. Further, by setting the access authority for each of the producers, the traders, and the consumers, those who do not own the access authority cannot read, write, rewrite, and erase the information.

The wireless IC tag can be used as follows. At the settlement, the information that the settlement has been made is written in the wireless IC tag, and the wireless IC tag is checked by a checking means provided at an exit whether or not the information that the settlement has been made is written in the wireless IC tag. If the IC tag is brought out from the store without making the settlement, the alarm rings. With this method, forgetting of the settlement and shoplifting can be prevented.

Further, in consideration of protecting customer's privacy, the following method is also possible. Product information is read out from a wireless IC tag at a cash register and any one of the followings is conducted: (1) data inputted in the wireless IC tag are locked by pin numbers or the like, (2) data itself inputted in the wireless IC tag are encrypted, (3) data inputted in the wireless IC tag are erased, and (4) data inputted in the wireless IC tag are destroyed. These can be achieved by using the memory described in other embodiment. Then, a checking means is provided at an exit, and whether any one of (1) to (4) has been performed or whether the data in the wireless IC tag are not processed at all is checked so that whether the settlement has been made or not is checked. In this way, whether the settlement has been made or not can be checked in the store, and it can prevent the information in the wireless IC tag from being read out against the owner's will outside the store.

Several methods are given to destroy the data inputted in the wireless IC tag of (4). For example, the followings are given: (a) a method in which only the data are destroyed by writing one or both of “0” (off) and “1” (on) in at least part of the electronic data in the wireless IC tag and (b) a method in which an excessive amount of current is flowed through the wireless IC tag to physically destroy part of a wiring of a semiconductor element in the wireless IC tag.

As another method for using a wireless IC tag, a quality control method or a handling method of a product can be a self-adjustable type by reading out information on a product with a wireless IC tag with the use of a reader of an electrical home appliance such as a refrigerator or a washing machine. Further, product information can also be displayed by having an electrical home appliance with a monitor.

For example, a product (for example, a food product) has a condition suitable for preservation in terms of temperature or humidity. In addition, it is important to set temperature inside a refrigerator at each season in respect of energy saving. However, it is very troublesome for consumers to adjust this by themselves. When the adjustment is neglected, a product may be damaged soon and even electric power may be consumed more than needed depending on a season.

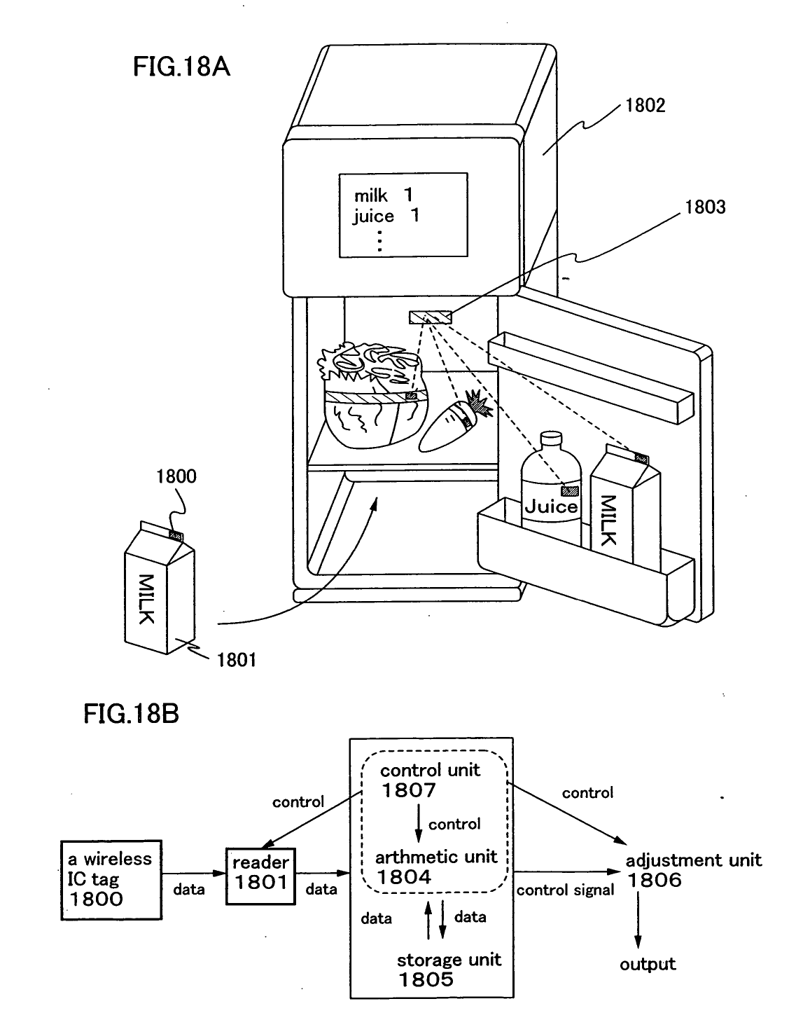

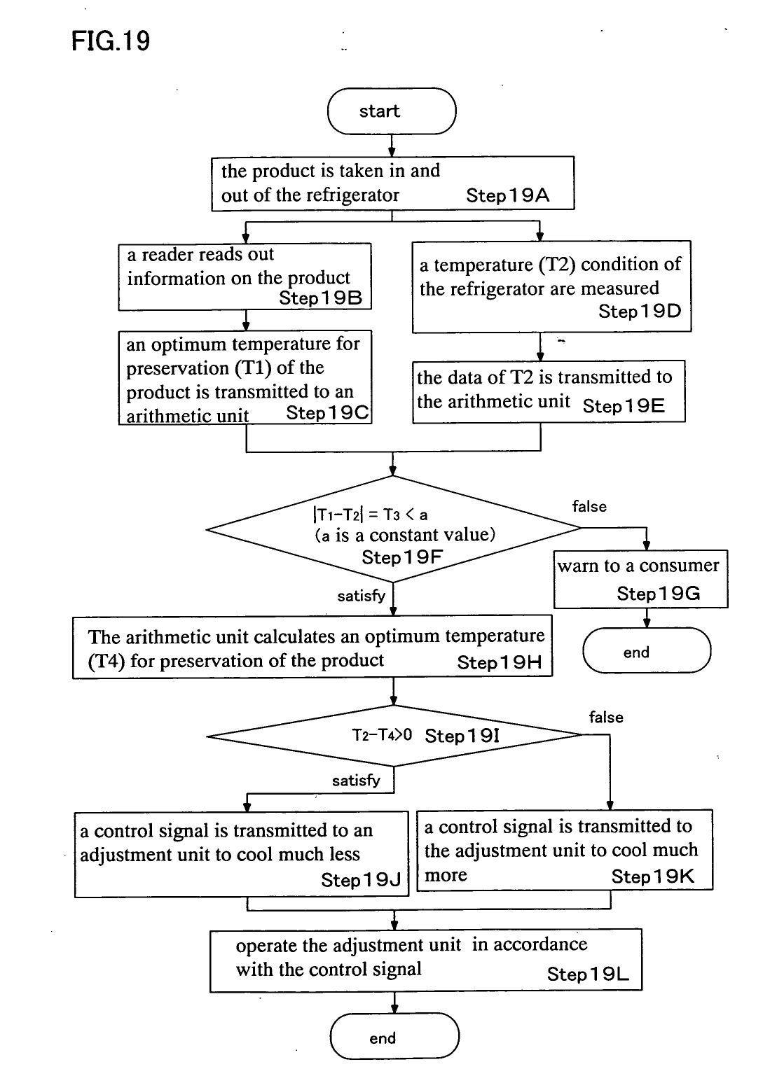

FIG. 18A shows the case where a product 1801 with a wireless IC tag 1800 is being taken in and out of a refrigerator 1802. The flow of data read out here is shown in FIG. 18B. In addition, a flow chart of a process performed in a refrigerator with taking the product 1801 in and out is shown in FIG. 19.

First, as shown in FIG. 18A, the product 1801 with a wireless IC tag is taken in and out of the refrigerator 1802 (Step 19A). At this time, a reader 1803 reads out information on the product taken in and out (Step 19B). Next, the product data is transmitted to an arithmetic unit 1804 of the refrigerator 1802 (Step 19C), and the arithmetic unit 1804 is made to store the product information to a storage unit 1805, if necessary. This data includes the type of a product, an optimum temperature for preservation (T₁), a humidity condition, an expiry date, or the like. At the same time, a temperature (T₂) and a humidity condition of the refrigerator 1802 are measured (Step 19D) and transmitted to the arithmetic unit 1804 (Step 19E). This data is stored to the storage unit 1805, if necessary. Note that the following description is made with attention to a temperature; however, other elements can be processed similarly.

Next, as shown in Step 19F, the arithmetic unit 1804 takes out data on an optimum temperature for preservation of the product that has taken in and out (T₁) and a temperature inside a refrigerator (T₂) and calculates an absolute value between T₁ and T₂, and it is compared whether T₂ and a constant value (a) follow the equation shown below.
|T₁−T₂|=T₃<a

In the case where T₃ takes a constant value (a) or more, in the words, when the above equation is false, it is inappropriate to preserve the product in the refrigerator 1802. Therefore, this is warned to a consumer by a means such as sound or light (Step 19G), and a temperature of the refrigerator 1802 is not changed. In the case where T₃ is within a constant value (a), in other words, when the above equation is satisfied, the following process will be performed subsequently.

The arithmetic unit 1804 calculates an optimum temperature for preservation of the product after taken in and out (T₄) (Step 19H). Further, this temperature (T₄) and a temperature inside the refrigerator are compared (Step 19I) and the strength of cooling is determined from the result. In the case of T₂>T₄, a control signal is transmitted to an adjustment unit 1806 to cool much less (Step 19J) and, in the case of T₂<T₄, a control signal is transmitted to the adjustment unit 1806 to cool much more (Step 19K). The adjustment unit 1806 adjusts a temperature of the refrigerator 1802 to be T₄ by operating the adjustment unit 1806 in accordance with the control signal (Step 19L).

Note that the input and output of the reader 1803, the arithmetic unit 1804, and the adjustment unit 1805 in the refrigerator 1802 is controlled by a control unit 1807. Note that a CPU may be used as the arithmetic unit 1804 and the control unit 1807.

As another function, it also becomes possible to turn down the cooling of the refrigerator 1802 when there are not so many products and to turn up the cooling when there are many products by grasping the type or the number of the product put in the refrigerator 1802. Further, it also becomes possible to turn down or up the cooling only for a specific position inside the refrigerator 1802. In addition, it is possible to confirm what is in the refrigerator 1802 without opening it by providing the refrigerator 1802 with a monitor 1808.

In addition, it is also possible to carry out a cooling method depending on an article put in the refrigerator. It is determined whether the article is to be cooled immediately or to be cooled gradually according to information on the wireless IC tag. A control signal is transmitted to the adjustment unit 1806 according to the determination and the adjustment unit 1806 adjusts the cooling according to the control signal.

Accordingly, a product can be preserved preferably for a long time and wasted electric power can be less consumed by controlling the condition inside the refrigerator depending on the situation. Note that a method for adjusting temperature is not limited to the method shown here.

This embodiment explains the refrigerator in which a food product is preserved. However, as for an article that is necessary to be preserved by adjusting temperature, humidity, brightness, or the like (for example, (1) a chemical substance or medical goods, (2) a living body of a cell, bacteria, a plant, an animal, or the like, (3) an article derived from a living body of an enzyme, DNA, or the like), the refrigerator can be used similarly by attaching a wireless IC tag where article information is inputted to a container or by attaching an wireless IC tag to a sample itself.

In the case of a washing machine, it is necessary to set an appropriate washing method, the type or amount of detergent, the amount of water used for washing, or the like. In general, the laundry is various in size or type and thus setting of the laundry is troublesome. In recent years, although a multifunction washing machine has been put on sale, a consumer cannot fully use the function of the washing machine in many cases.

In a dewatering washing machine with one tub which has been generally put on sale, the weight of the laundry is measured by measuring power for turning on the washing and dewatering tub after putting the laundry in the washing and dewatering tub and thus the amount of water is determined by the weight of this laundry. Thus, even in the case of the laundry with the same weight, the laundry which is large and takes up much space like sheets and the small laundry like a denim jacket are washed with the same amount of water and washing method. Since the amount of detergent is set in accordance with the amount of water used for washing, the amount of detergent may not be appropriate in such a case mentioned above.

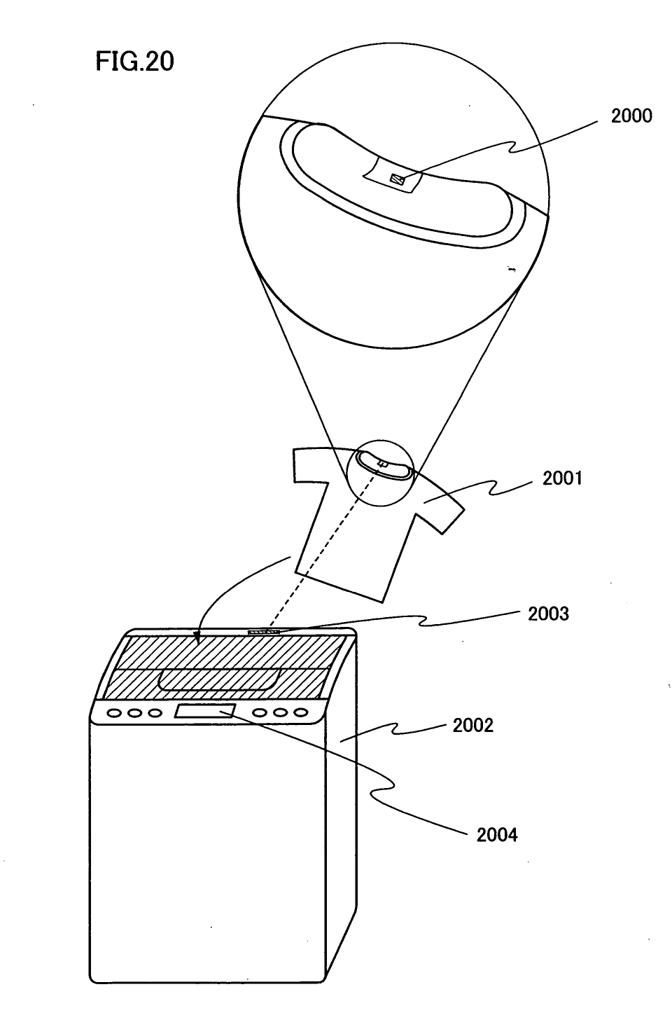

Thus, as shown in FIG. 20, when a laundry 2001 where a wireless IC tag 2000 is implanted into clothes is put in a washing machine 2002, a reader 2003 attached to the washing machine reads out information on the type, size, weight, material, or the like, and the information is transmitted to an arithmetic unit. The arithmetic unit determines an appropriate washing course, the type and amount of detergent, and the amount of water from this information on the laundry. Then, the type and amount of detergent to be put are displayed on a monitor 2004 attached to the washing machine. A consumer may put detergent according to the display and push the start button of the washing machine. Accordingly, washing starts after setting regarding washing is automatically done. Note that the wireless IC tag implanted into clothes needs to be covered with a water-resistant substance. For example, water-resistant resin, ceramic, or the like can be used.

### Embodiment 5

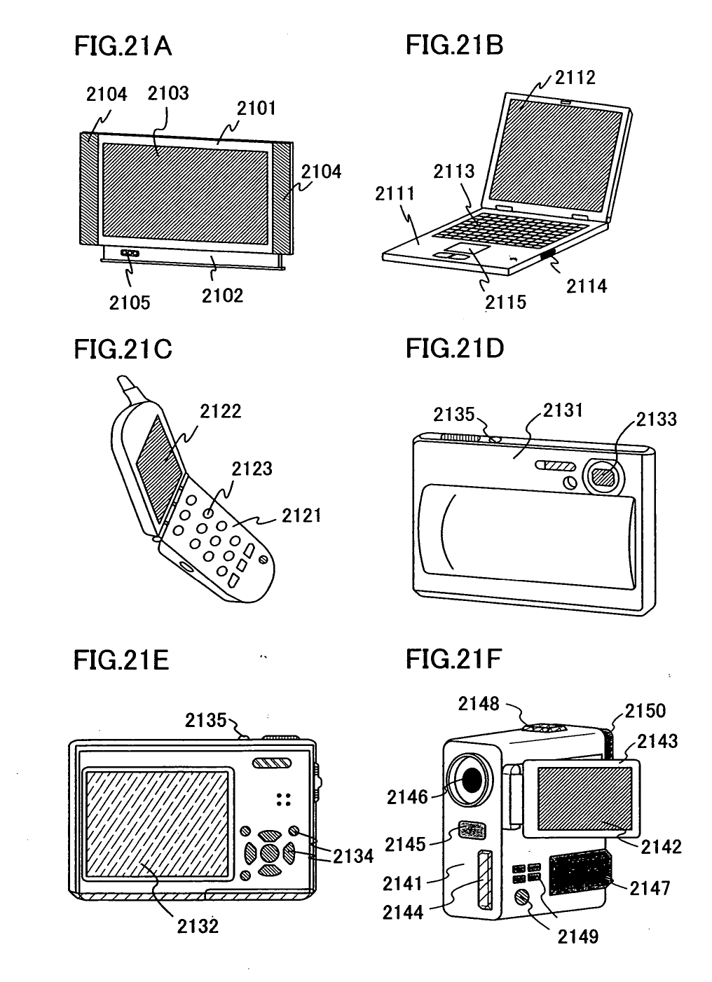

Various electronic devices such as a display device, for example, a display, a reflection type projector, or a head mounted display; an audio reproducing device; a navigation system; a portable information terminal; a game machine; a digital still camera; or a device for reproducing picture and projected images can be completed by mounting a TFT manufactured according to the present invention as an integrated CPU, a memory, an IC, or the like or by using the TFT as a panel. The specific example will be explained with reference to FIGS. 21A to 21F.

There can be less dimensional change in width of a sidewall when a silicon nitride film is etched because high anisotropy can be obtained according to the present invention compared with the conventional technique. Further, it is possible to form an LDD region preferably in accordance with this sidewall. Thus, an electronic device having a TFT that is formed according to the present invention has preferable quality without variation.

FIG. 21A shows a display device, which includes a housing 2101, a supporting stand 2102, a display portion 2103, speaker portions 2104, a video input terminal 2105, and the like. This display device is manufactured by using a TFT formed by the manufacturing method shown in other embodiment for a driver IC, the display portion 2103, or the like. Note that a liquid crystal display device, a light-emitting display device, or the like is used as the display device, and specifically all display devices for information display such as for a computer, television broadcast reception, and advertisement display are included.

FIG. 21B shows a computer, which includes a housing 2111, a display portion 2112, a keyboard 2113, an external connection port 2114, a pointing mouse 2115, and the like. A TFT formed according to the present invention can be applied to a driver IC for display and a semiconductor device inside a main body such as a CPU or a memory as well as a pixel portion of the display portion 2112.

In addition, FIG. 21C shows a cellular phone as a typical example of portable information terminals. This cellular phone includes a housing 2121, a display portion 2122, operation keys 2123, a sensor portion 2124, and the like. A TFT formed according to the present invention can be used for a driver IC for display, a memory, an audio processing circuit, or the like as well as a pixel portion of the display portion 2122 or the sensor portion 2124. The sensor portion 2124 has an optical sensor element, and the amount of consumption current of the cellular phone can be suppressed by controlling the brightness of the display portion 2122 based on the illumination intensity obtained by the sensor portion 2124, or by performing the lighting control of the operation keys 2123 corresponding to the illumination intensity obtained by the sensor portion 2124.

A semiconductor material formed according to the present invention can also be used for an electronic device such as a PDA (personal digital assistant), a digital camera, or a compact game machine, as well as the above cellular-phone. For example, it is possible to form a functional circuit such as a CPU, a memory, or a sensor and to apply the semiconductor material to pixel portions of these electronic devices and a driver IC for display.

FIGS. 21D and 21E each show a digital camera. Note that FIG. 21E shows a rear side of FIG. 21D. This digital camera includes a housing 2131, a display portion 2132, a lens 2133, operation keys 2134, a shutter 2135, and the like. A TFT formed according to the present invention can be used for a pixel portion of the display portion 2132, a driver IC for driving the display portion 2132, a memory, or the like.

FIG. 21F shows a digital video camera. This digital video camera includes a main body 2141, a display portion 2142, a housing 2143, an external connection port 2144, a remote control receiving portion 2145, an image receiving portion 2146, a battery 2147, an audio input portion 2148, operation keys 2149, an eyepiece portion 2150, and the like. A TFT formed according to the present invention can be used for a pixel portion of the display portion 2142, a driver IC for driving the display portion 2142, a memory, a digital input processor, or the like.

As mentioned above, the application range of a semiconductor device manufactured according to the present invention is extremely broad and the semiconductor device manufactured according to the present invention can be used for various electronic devices. Note that, as display devices used for these electronic devices, a heat-resistant plastic substrate can also be used as well as glass substrate depending on the size or intensity, or the purpose of use. Accordingly, it can be tried to realize further weight saving.

In addition, this embodiment can be arbitrarily combined with the embodiment mode or other embodiments.

### Embodiment 6

In this embodiment, a result of measurement how a silicon nitride film is etched and a sidewall is formed when the flow rate of a hydrogen bromide (HBr) gas is changed will be shown.

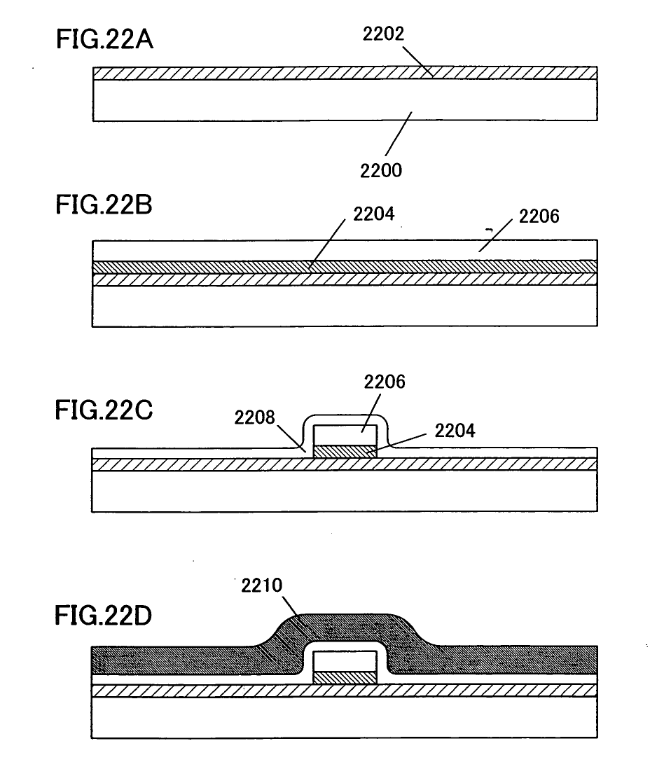

A sample to be etched was manufactured as shown below. First, as shown in FIG. 22A, an insulating substrate 2200 such as a glass substrate is prepared. In this embodiment, a glass substrate was used as the insulating substrate 2200. As shown in other embodiments, as well as a glass substrate such as an alumino borosilicate glass or a barium borosilicate glass, a quartz substrate, a ceramic substrate, a stainless steel substrate, or the like, a substrate made from synthetic resin such as plastic typified by PET (polyethylene terephthalate), PES (polyethersulfone resin), or PEN (polyethylene naphthalate); acryl; or the like can also be used.

Next, a silicon oxide film containing nitrogen was formed in 100 nm thick over this insulating substrate 2200 with the use of a plasma CVD method, and the silicon oxide film containing nitrogen is used as a base film 2202 (FIG. 22A). Generally, the base film 2202 is provided to prevent an alkali metal such as natrium or an alkaline-earth metal contained in the insulating substrate from diffusing into a semiconductor and adversely affecting the characteristic of a semiconductor element. Therefore, the base film 2202 is formed with an insulating film such as silicon oxide, silicon nitride, or silicon nitride containing oxygen which can suppress the diffusion of an alkali metal or an alkaline-earth metal into the semiconductor. When a substrate such as a quartz substrate is used which hardly diffuses the impurities, the base film 2202 is not necessarily provided. In this embodiment, a semiconductor film is not provided because the film is only for observing the state of forming a sidewall; however, a semiconductor film may be formed as shown in other embodiments in the case of actually forming a semiconductor device.

Then, tantalum nitride (TaN) is formed in 30 nm thick as a first conductive film 2204 as shown in FIG. 22B. Further, tungsten (W) is formed in 370 nm thick over the first conductive film as a second conductive film 2206. Furthermore, a resist mask for forming a pattern of the first conductive film 2204 and the second conductive film 2206 is formed, and an etching process of the first conductive film 2204 and the second conductive film 2206 is performed so that the conductive films are each formed into an island shape with this resist mask (FIG. 22C). This portion corresponds to a gate electrode of a TFT.

Subsequently, silicon oxynitride (SiON) is deposited in 50 nm thick as an insulating film 2208 so as to cover the base film, and the island-shaped first conductive film 2204 and second conductive film 2206 (FIG. 22C). A deposition method can be a known method such as a plasma CVD method or a sputtering method. In this embodiment, the insulating film 2208 is used as a stopper film of etching which will be performed subsequently.

Next, a silicon nitride film 2210 is formed in 300 nm thick so as to cover the insulating film 2208 as shown in FIG. 22D. The silicon nitride film is formed using a plasma CVD method; however, other known method can also be used to form the film. The sample was manufactured by performing the above processes.

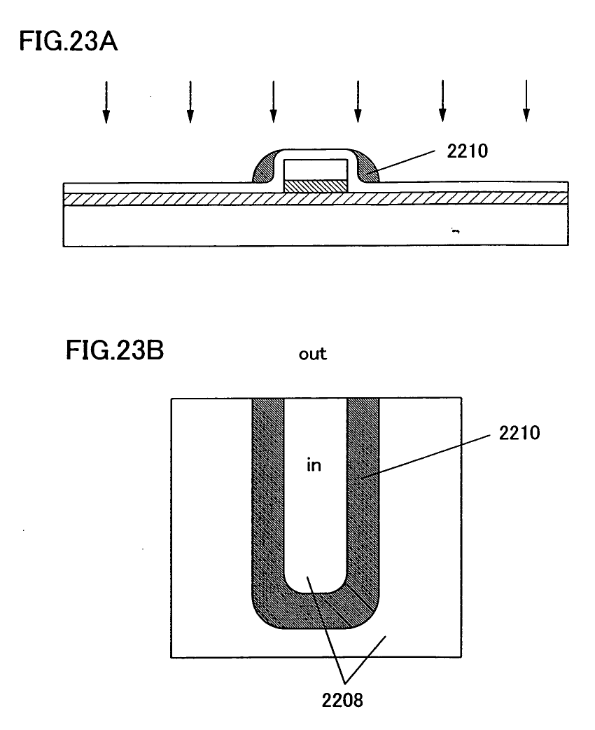

Here, dry etching of the silicon nitride film 2210 is performed using a gas containing bromine as shown in FIG. 23A. As an etching gas, a mixed gas of hydrogen bromide, chlorine, and oxygen is used. In this embodiment, the flow rate of chlorine is fixed to 44 sccm, the flow rate of oxygen is fixed to 6 sccm and the flow rate of hydrogen bromide is changed to make three kinds of mixed gases. The flow rate of hydrogen bromide used in this embodiment is three kinds of 50 sccm, 100 sccm, and 130 sccm (hereinafter referred to as a sample 1, a sample 2, and a sample 3, respectively). Dry etching is performed using an ICP (Inductively Coupled Plasma) apparatus with the use of these mixed gases. Note that a pressure is set to 1.6 Pa; a high frequency of ICP, 450 W; a high frequency of BIAS, 150 W; and a temperature in the etching apparatus, 70° C. A high frequency applied to ICP serves to decompose process gas, and a high frequency applied to BIAS serves to accelerate etching species (ion). According to this step, a sidewall is formed.

The end of etching is obtained from the change in plasma waveform. When each plasma waveform of the samples 1, 2, and 3 is observed, the change in waveforms that derived from starting etching a substance other than silicon nitride at 158 seconds, 180 seconds, and 191 seconds, respectively, was found. Therefore, it is considered that a sidewall is formed at this point. According to the time for observing a plasma waveform, it is found that a longer time is taken in the case where there is a large flow rate of hydrogen bromide.

This process is performed simultaneously at four points over the substrate, and a sidewall is formed at each point. The width of the sidewall is measured using a means of a measurement SEM. FIG. 23B shows a top view of FIG. 23A. The total width including the sidewall (referred to as out) and a width excluding the sidewall (referred to as in) are measured, which are obtained in an equation of (the width of the sidewall)=((out)−(in))/2.

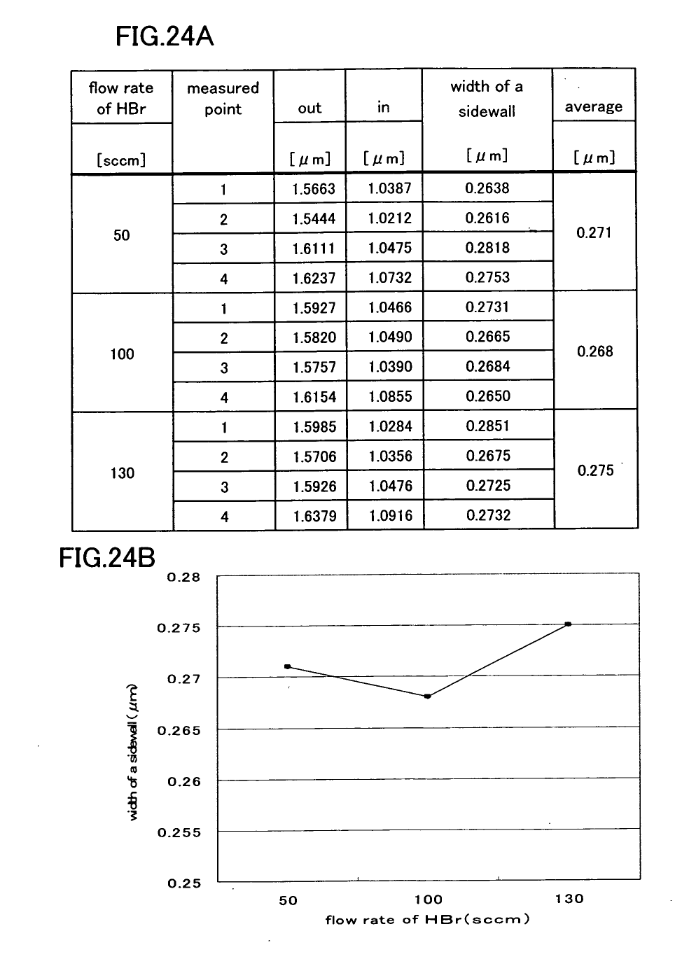

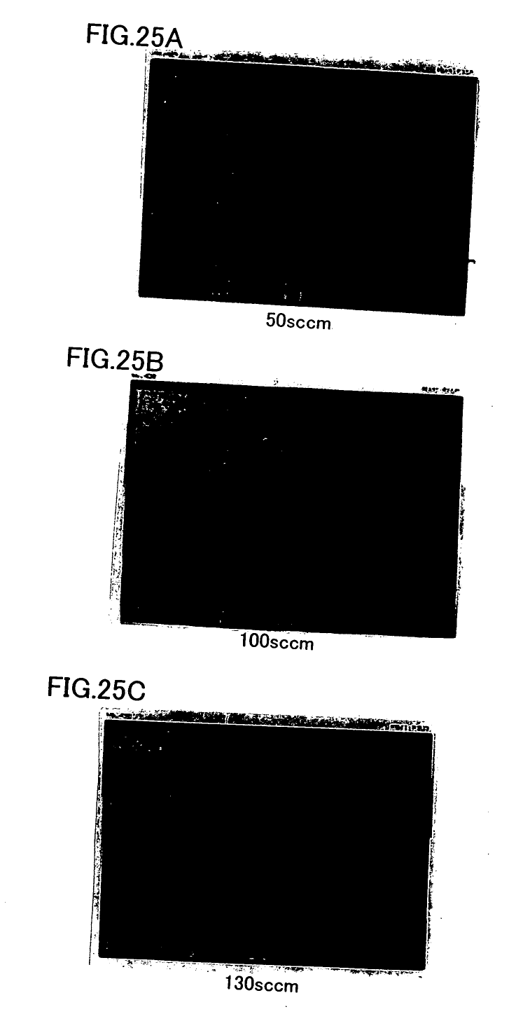

As shown in FIGS. 24A and 24B, the average values of the width of the sidewalls in the samples 1, 2, and 3 were 0.271 μm, 0.268 μm, and 0.275 μm, respectively. In addition, SEM photographs at the end of etching the samples 1, 2, and 3 are shown in FIGS. 25A to 25C. According to these results, it was found that the width of the sidewalls does not depend on the flow rate of hydrogen bromide, in other words, the concentration of hydrogen bromide; thus, the sidewalls are formed to have almost the same length in widths.

From the above result, it was found that a sidewall in approximately 0.27 μm thick can be formed even in the embodiment mode or other embodiments by performing an etching process of silicon nitride when the flow rate of chlorine is fixed to 44 sccm and the flow rate of oxygen to 6 sccm as long as the flow rate of hydrogen bromide is 50 sccm or more and 130 sccm or less.

### Embodiment 7

In this embodiment, a photo IC and a manufacturing method thereof will be explained as an example of an element manufactured according to the present invention.

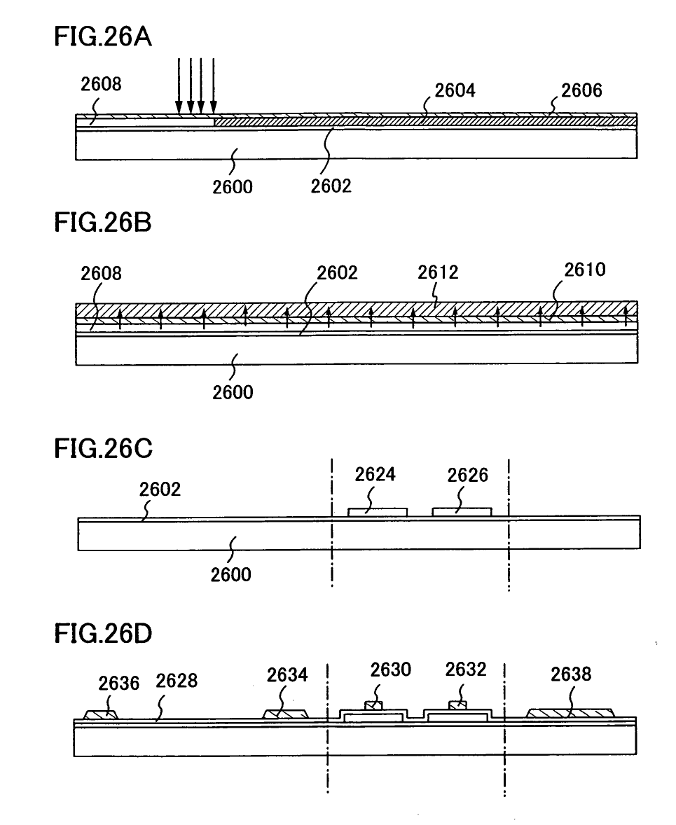

First, an element is formed over a substrate (first substrate 2600) in FIG. 26A. Herein AN 100 which is one of glass substrates is used as the substrate 2600.

Next, a silicon oxide film containing nitrogen (film thickness: 100 nm) to serve as a base insulating film 2602 is formed by a plasma CVD method. Further, a semiconductor film is stacked in thickness of 20 nm or more and 150 nm or less, preferably 30 nm or more and 80 nm or less without being exposed to an atmosphere. In this embodiment, an amorphous silicon film containing hydrogen is formed as an amorphous semiconductor film 2604.

The base insulating film 2602 may be stacked using a silicon oxide film, a silicon nitride film, and a silicon oxide film containing nitrogen. For example, a silicon nitride film containing oxygen in 50 nm thick and further a silicon oxide film containing nitrogen in 100 nm thick may be stacked as the base insulating film 2602. Note that the silicon oxide film containing nitrogen or the silicon nitride film serves as a blocking layer for preventing impurity diffusion of an alkali metal or the like from the glass substrate.

Then, the above amorphous semiconductor film 2604 is crystallized by a solid phase epitaxy method, a laser crystallization method, a crystallization method using a catalytic metal, or the like to form, for example, a polycrystalline silicon film 2608 as a type of semiconductor films having a crystalline structure (crystalline semiconductor films).

In this embodiment, the polycrystalline silicon film 2608 is formed with the use of a crystallization method using a catalyst element. First, the surface of the amorphous semiconductor film 2604 is coated partially or entirely with a solution containing nickel, for example, a solution of nickel acetate of 10 to 100 ppm by weight with the use of a spinner. In addition, a method for dispersing a nickel element over the entire surface with a sputtering method may be used instead of the treatment for coating with a spinner as mentioned above. Besides, the nickel element can be added using a vapor deposition method or plasma processing, or the like. Note that a catalyst element that can be used here is not only nickel but also germanium, iron, palladium, tin, lead, cobalt, platinum, copper, gold, or the like. The catalyst with which the surface of the amorphous semiconductor film 2604 is coated partially or entirely is shown as reference numeral 2606 in FIG. 26A.

Note that, in order to suppress the growth direction of the crystallization in a direction vertical to the surface of the substrate 2600 in crystallizing the semiconductor film, the entire surface of the semiconductor film may be coated with a solution containing a catalyst element. In addition, in order to suppress the growth direction of the crystallization in a direction parallel to the surface of the substrate 2600, the surface of the semiconductor film may be partially coated with the solution containing a catalyst element.

Subsequently, a semiconductor film having a crystalline structure (herein, a polycrystalline silicon film) is formed by performing heat treatment to be crystallized. Herein, heat treatment (at 550° C. for 4 hours) for crystallization is performed after heat treatment (at 500° C. for an hour). The amorphous semiconductor film 2604 and the catalyst element respond by the former heat treatment, and a compound is formed over the surface of the face where the amorphous semiconductor film 2604 and the catalyst element is in contact and in the vicinity thereof. Crystal growth of this compound occurs as being a nucleus at the next heat treatment. The crystallization temperature is made low and shortened because of action of a metal element having catalyst action. According to such heat treatment, the polycrystalline silicon film can be obtained. The crystallinity is improved with the use of the catalyst element. Consequently, the variation in mobility between elements, a threshold value, and on current can be suppressed.

Next, an oxide film over the surface of the polycrystalline silicon film 2608 is removed with rare hydrofluoric acid or the like. Thereafter, laser beam irradiation is performed in order to increase the crystallization rate and to correct defects which remain in the crystalline grains.

Note that, in the case of obtaining a crystalline semiconductor film by crystallizing an amorphous semiconductor film with a laser crystallization method or the case of performing laser irradiation to correct defects which remain in the crystalline grains after obtaining a semiconductor film having a crystalline structure, it is much preferable to use a CW laser or a pulsed laser having a high oscillation frequency. Note that the oscillation frequency of the pulsed laser used here is much preferable to be 10 MHz or more.

Note that, in the case of performing laser irradiation in an atmosphere or an oxygen atmosphere, an oxide film is formed over the surface by laser beam irradiation.

Then, a barrier layer 2610 formed by an oxide film in thickness of 1 to 5 nm is formed by processing the surface for 120 seconds with ozone water (FIG. 26B). Note that, by performing laser beam irradiation in an atmosphere or an oxygen atmosphere, when the oxide film is formed over the polycrystalline silicon film 2608, the barrier layer 2610 is formed in thickness of 1 nm or more and 5 nm or less by performing this process.

This barrier layer 2610 is formed to remove the catalyst element added for crystallization, for example, nickel (Ni) from the film. Herein, the barrier layer 2610 is formed using ozone water. However, the barrier layer 2610 may be formed by depositing an oxide film in thickness of approximately 1 to 10 nm with a method for oxidizing the surface of a semiconductor film having a crystalline structure with irradiation of an ultra-violet ray under an oxygen atmosphere, a method for oxidizing the surface of a semiconductor film having a crystalline structure by oxygen plasma processing, a plasma CVD method, a sputtering method, a vapor deposition method, or the like. In addition, the oxide film formed by laser beam irradiation before forming the barrier layer 2610 may be removed.

Subsequently, an amorphous silicon film 2612 containing a rare gas element to be a gettering site is formed over the barrier layer 2610 by a sputtering method to be in thickness of 10 to 400 nm, in this embodiment, 100 nm thick (FIG. 26B). In this embodiment, the amorphous silicon film 2612 is formed under an atmosphere containing argon with the use of a silicon target. In the case of forming the amorphous silicon film containing an argon element with the use of a plasma CVD method, the deposition condition is as follows: a flow rate of monosilane and argon (SiH₄:Ar) is set to 1:99; a deposition pressure, 6.665 Pa; an RF power density, 0.087 W/cm²; and a deposition temperature, 350° C. It is desirable that the density of the amorphous silicon film 2612 is lower than that of the polycrystalline silicon film 2608 in order to increase the etching selection ratio of the amorphous silicon film 2612 formed here to the polycrystalline silicon film 2608. As the rare gas element, one or more of helium (He), neon (Ne), argon (Ar), krypton (Kr), and xenon (Xe) can be used.

Thereafter, the amorphous silicon film 2612 is put in a furnace heated at 650° C. to perform heat treatment for 3 minutes and thus the catalyst element is removed (gettering is performed) (FIG. 26B). Accordingly, the concentration of the catalyst element contained in the polycrystalline silicon film 2608 is reduced. A lamp-annealing device may be used instead of the furnace. According to the heat treatment, the catalyst element in the polycrystalline silicon film 2608 moves to a semiconductor film for gettering, in other words, the amorphous silicon film 2612 due to diffusion as shown by an arrow.

Next, after selectively removing the amorphous silicon film 2612 containing an argon element which is a gettering site with the use of the barrier layer 2610 as an etching stopper, the barrier layer 2610 is selectively removed with rare hydrofluoric acid. Note that, in gettering, nickel tends to move to a region high in oxygen concentration; therefore, it is desirable to remove the barrier layer 2610 made of the oxide film after the gettering.

Note that, in the case where a semiconductor film is not crystallized using a catalyst element, the above steps such as for forming the barrier layer 2610, forming a gettering site (the amorphous silicon film 2612 containing a rare gas element), performing heat treatment for gettering, removing the gettering site, removing the barrier layer, or the like is not necessary.

Then, over the surface of the obtained semiconductor film having a crystalline structure (for example, a crystalline silicon film), a thin oxide film is formed with ozone water, a resist is further formed over the oxide film, and light exposure is performed; therefore, a mask the material of which is to be the resist is formed. Further, semiconductor films separated in an island shape (hereinafter, referred to as an island-shaped semiconductor film in this specification) 2624 and 2626 are formed by performing an etching process (see FIG. 26C). After forming the island-shaped semiconductor films 2624 and 2626, the mask the material of which is to be the resist is removed.

Subsequently, a very small amount of impurity element (boron or phosphorus) is doped in order to control the threshold value of a TFT, if necessary. Herein, an ion doping method in which diborane (B₂H₆) is plasma-excited without mass-separation is used.

Next, after washing the surface of the island-shaped semiconductor films 2624 and 2626 simultaneously with removing the oxide film with etchant containing hydrofluoric acid, an insulating film containing silicon as the main component which is to be a gate insulating film 2628 is formed (FIG. 26D). Herein, a silicon oxide film containing nitrogen (composition ratio: Si=32%, O=59%, N=7%, and H=2%) is formed in 115 nm thick with the use of a plasma CVD method.

Then, after forming a metal film over the gate insulating film 2628, a process (patterning) for forming the metal film in a predetermined shape is performed using a second photomask, and gate electrodes 2630 and 2632, wirings 2634 and 2636, and a terminal electrode 2638 are formed (FIG. 26D). As this metal film, for example, a film where tantalum nitride (TaN) and tungsten (W) are stacked in 30 nm and 370 nm thick, respectively, is used.

In addition, as the gate electrodes 2630 and 2632, the wirings 2634 and 2636, and the terminal electrode 2638, the following can be used besides the above: a single layer film made of one or more elements of titanium (Ti), tungsten (W), tantalum (Ta), molybdenum (Mo), neodymium (Nd), cobalt (Co), zirconium (Zr), zinc (Zn), ruthenium (Ru), rhodium (Rh), palladium (Pd), osmium (Os), iridium (Ir), platinum (Pt), aluminum (Al), gold (Au), silver (Ag), and copper (Cu), or an alloy material or a compound material containing the elements as the main component, or nitride thereof. For example, a single layer film made of titanium nitride, tungsten nitride, tantalum nitride, or molybdenum nitride can be given.

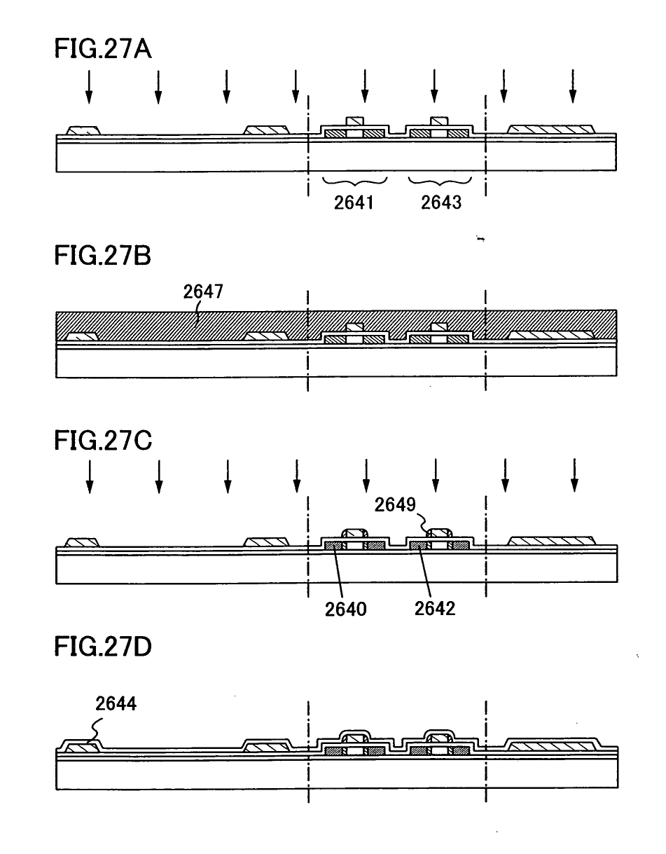

Subsequently, impurity imparting one conductivity is introduced to the island-shaped semiconductor films 2624 and 2626. In this embodiment, N-channel TFTs 2641 and 2643 are formed; therefore, an N-type impurity, for example, phosphorus (P) or arsenic (As) is introduced to the island-shaped semiconductor films 2624 and 2626 (see FIG. 27A).

Next, a silicon nitride film 2647 is formed over the entire surface in 300 nm thick (FIG. 27B). The silicon nitride film 2647 can be formed with the use of a plasma CVD method or the like. Further, an etching process of the silicon nitride film 2647 is performed using a gas containing bromine. In this embodiment, hydrogen bromide, chlorine, and oxygen are mixed as an etching gas to have the flow rate of 100:44:6 and a plasma etching process is performed using an ICP apparatus to form a sidewall 2649 as shown in FIG. 27C. Note that the flow rate of hydrogen bromide contained in this etching gas may be changed. Specifically, when the flow rate of chlorine and oxygen is fixed to 44:6, the flow rate of hydrogen bromide may be 50 or more and 130 or less. Within this range, the sidewall is formed in a definite size regardless of the flow rate of hydrogen bromide.

Note that, in the above etching process, a pressure is set to 1.6 Pa; a high frequency of ICP, 450 W; and a high frequency of BIAS, 150 W. A high frequency applied to ICP serves to decompose process gas, and a high frequency applied to BIAS serves to accelerate etching species (ion).

An ICP method is used as a dry etching method in this embodiment; however, the method is not limited thereto. In the same manner, an etching method such as parallel plate type RIE (Reactive Ion Etching), magnetron type RIE, two cycles type RIE, microwave type RIE, ECR (Electron Cyclotron Resonance) plasma etching, or helicon type plasma etching can be used.

Then, a source or drain region 2640 of a TFT 2641, a source or drain region 2642 of a TFT 2643, and an LDD region 2649 are formed by introducing an ion imparting N-type conductivity in a higher dose amount than the above by using a sidewall 2649 as a mask. Treatment is performed by laser annealing, lamp annealing, or furnace annealing after completing impurity introduction to activate the introduced impurity and to recover damage of crystallinity due to impurity introduction.

Subsequently, after forming a first interlayer insulating film including a silicon oxide film (not shown) by a CVD method in 50 nm thick, a step of performing an activation process of the impurity element added to each of the island-shaped semiconductor films 2624 and 2626 is performed. This activation step is performed by a rapid thermal annealing (RTA) method using a lamp light source, an irradiation method of a laser beam such as a YAG laser or an excimer laser, heat treatment using a furnace, or a method with any of the combination thereof.

Next, a second interlayer insulating film 2644 including a silicon nitride film containing hydrogen and oxygen is formed (FIG. 27D). In this embodiment, the second interlayer insulating film 2644 is formed in 10 nm thick as an example.

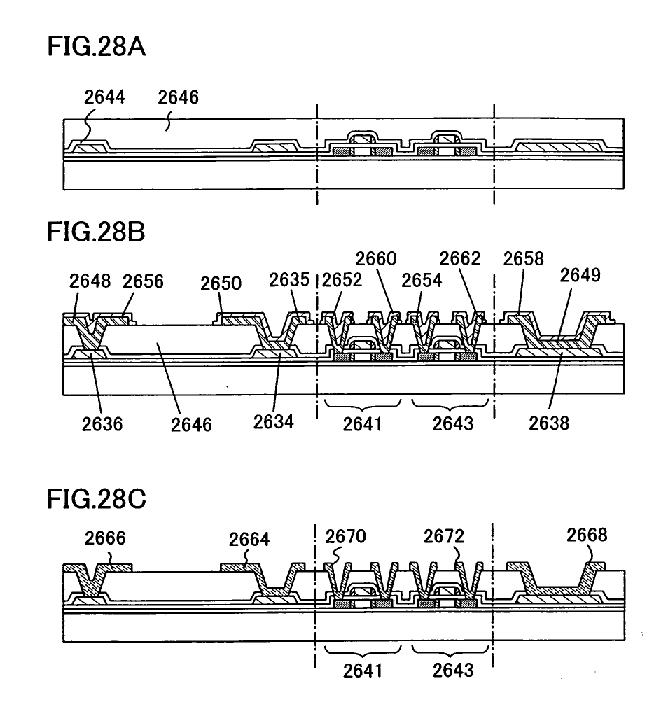

Then, a third interlayer insulating film 2646 made from an insulating material is formed over the second interlayer insulating film 2644 (see FIG. 28A). An insulating film obtained by a CVD method can be used for the third interlayer insulating film 2646. A silicon oxide film containing nitrogen is formed in 900 nm thick as the third interlayer insulating film 2646 in order to improve adhesiveness in this embodiment.

Subsequently, heat treatment (heat treatment at temperatures of 300° C. or more and 550° C. or less for an hour or more and 12 hours or less, for example, heat treatment at 410° C. in a nitrogen atmosphere for an hour) to hydrogenate the island-shaped semiconductor films 2624 and 2626. This step is performed to terminate a dangling bond of the island-shaped semiconductor films 2624 and 2626 by hydrogen contained in the second interlayer insulating film 2644. The island-shaped semiconductor films 2624 and 2626 can be hydrogenated regardless of the gate insulating film 2628.

In addition, it is possible to use an insulating film using siloxane and a multilayer structure thereof as the third interlayer insulating film 2646. Siloxane is a substance that is composed of a skeleton structure formed by the bond (siloxane bond) of silicon and oxygen, in which silicon is bonded to at least one kind of fluorine, aliphatic hydrocarbon, or aromatic hydrocarbon.

When an insulating film using siloxane and a multilayer structure thereof is used as the third interlayer insulating film 2646, after forming the second interlayer insulating film 2644, heat treatment for hydrogenating the island-shaped semiconductor films 2624 and 2626 can be performed and then the third interlayer insulating film 2646 can also be formed.

Next, a resist mask is formed using a third photomask to form a contact hole by selectively etching the first interlayer insulating film, the second interlayer insulating film 2644, the third interlayer insulating film 2646, and the gate insulating film 2628. Then, the resist mask is removed.

Note that the third interlayer insulating film 2646 may be formed, if necessary. When the third interlayer insulating film 2646 is not formed, a contact hole is formed by selectively etching the first interlayer insulating film, the second interlayer insulating film 2644, and the gate insulating film 2628 after forming the second interlayer insulating film 2644.

Then, after depositing a metal film stack with the use of a sputtering method, a resist mask is formed using a fourth photomask and the metal film is selectively etched to form a wiring 2635, a connection electrode 2648, a terminal electrode 2649, an electrode (hereinafter, referred to as a source or drain electrode) 2652 connecting to the source or drain region 2640 of the TFT 2641, and an electrode (hereinafter, referred to as a source or drain electrode) 2654 connecting to the source or drain region 2642 of the TFT 2643. Then, the resist mask is removed. Note that the metal film of this embodiment is a stacked layer of a Ti film in 100 nm thick, an Al film in 350 nm thick containing a slight amount of Si, and a Ti film in 100 nm thick.

Subsequently, a conductive metal film (titanium (Ti), molybdenum (Mo), or the like) that is unlikely to be alloy even being reacted with a photoelectric conversion layer (typically, amorphous silicon) which will be formed subsequently is deposited. Thereafter, a resist mask is formed using a fifth photomask and the conductive metal film is selectively etched to form a protective electrode 2650 connected to the wiring 2634 (see FIG. 28B). A Ti film in 200 nm thick that is obtained by a sputtering method is used here. Note that the connection electrode 2648, the terminal electrode 2638, the source or drain electrode 2652 of the TFT 2641, and the source or drain electrode 2654 of the TFT 2643 are also covered with the conductive metal film similarly, and protective electrodes 2656, 2658, 2660, and 2662 are formed, respectively. Thus, in the conductive metal film, the Al film in the second layer of these electrodes also covers the side surfaces of the protective electrodes 2650, 2656, 2658, 2660, and 2662, and the conductive metal film can also prevents an aluminum atom from being diffused in the photoelectric conversion layer.

However, a protective electrode may not be necessarily formed when the wiring 2634, the connection electrode 2648, the terminal electrode 2638, the source or drain electrode 2654 of the TFT 2641, and the source or drain electrode 2654 of the TFT 2643 are each formed of a conductive film in a single layer, in other words, when a wiring 2664, a connection electrode 2666, a terminal electrode 2668, a source or drain electrode 2670 of a TFT 2641, and a source or drain electrode 2672 of a TFT 2643 are formed instead of these electrodes and the wiring as shown in FIG. 28C.

As shown in FIG. 28C, when the wiring 2664, the connection electrode 2666, the terminal electrode 2668, the source or drain electrode 2670 of the TFT 2641, and the source or drain electrode 2672 of the TFT 2643 are each formed of a conductive film in a single layer, a titanium film (Ti film) is preferable in terms of heat resistance, conductivity, and the like. In addition, instead of the titanium film, a single layer film made of one or more elements of tungsten (W), tantalum (Ta), molybdenum (Mo), neodymium (Nd), cobalt (Co), zirconium (Zr), zinc (Zn), ruthenium (Ru), rhodium (Rh), palladium (Pd), osmium (Os), iridium (Ir), and platinum (Pt), or an alloy material or a compound material containing the elements as the main component, or a single layer film made of nitride thereof, for example, titanium nitride, tungsten nitride, tantalum nitride, or molybdenum nitride can be used. By forming the wiring 2664, the connection electrode 2666, the terminal electrode 2668, the source or drain electrode 2670 of the TFT 2641, and the source or drain electrode 2672 of the TFT 2643 each in a single layer, the number of deposition can be reduced in the manufacturing process.

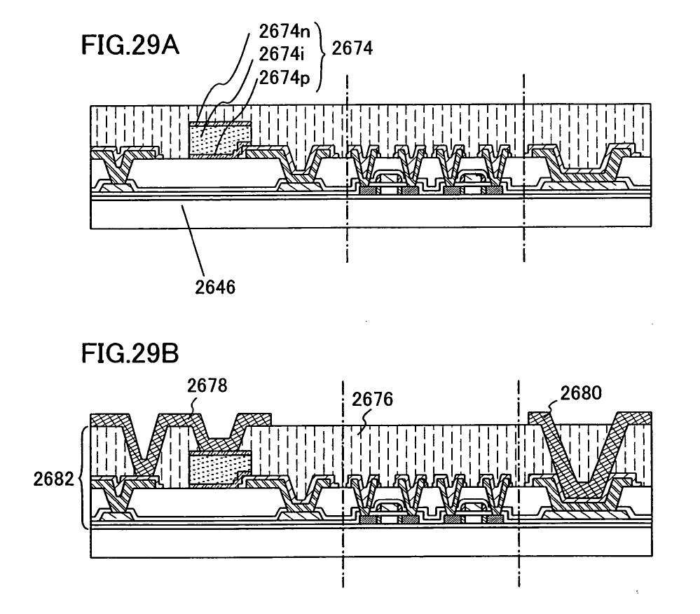

Next, a photoelectric conversion layer 2674 including a P-type semiconductor layer 2674p, an I-type semiconductor layer 2674i, and an N-type semiconductor layer 2674n is formed over the third interlayer insulating film 2646 (FIG. 29A).

The P-type semiconductor layer 2674p is preferably formed depositing an amorphous silicon film containing an impurity element belonging to Group 13, for example, boron (B) by a plasma CVD method.

In addition, the wiring 2634 and the protective electrode 2650 are electrically connected to the lowest layer of the photoelectric conversion layer 2674, which is the P-type semiconductor layer 2674p in this embodiment.

The lowest layer of the photoelectric conversion layer 2674 is in contact with the top face of the wiring 2664 when the wiring 2664, the connection electrode 2666, the terminal electrode 2668, the source or drain electrode 2670 of the TFT 2641, and the source or drain electrode 2672 of the TFT 2643 are each formed of a conductive film in a single layer without forming a protective electrode as shown in FIG. 28C.

After forming the P-type semiconductor layer 2674p, further, the I-type semiconductor layer 2674i and the N-type semiconductor layer 2674n are sequentially formed. Accordingly, the photoelectric conversion layer having the P-type semiconductor layer 2674p, the i-type semiconductor layer 2674i, and the N-type semiconductor layer 2674n is formed (FIG. 29A).

As the I-type semiconductor layer 2674i, an amorphous silicon film may be formed by a plasma CVD method, for example. In addition, as the N-type semiconductor layer 2674n, an amorphous silicon film containing an impurity element belonging to Group 15, for example, phosphorus (P) may be formed, or an impurity element belonging to Group 15 may be introduced after forming the amorphous silicon film.

In addition, as the P-type semiconductor layer 2674p, the I-type semiconductor layer 2674i, and the N-type semiconductor layer 2674n, a semi-amorphous semiconductor film may also be used as well as the amorphous semiconductor film.

Then, a sealing layer 2676 made of an insulator material (for example, an inorganic insulating film containing silicon) is formed in thickness of 1 to 30 μm over the entire surface. A silicon oxide film containing nitrogen in 1 μm thick is formed here as the insulator material film by a CVD method. It is tried to enhance the adhesiveness by using the insulating film formed by a CVD method for the sealing layer 2676 (FIG. 29A).

Subsequently, terminal electrodes 2678 and 2680 are formed by a sputtering method after providing an opening by etching the sealing layer 2676 (FIG. 29B). The terminal electrodes 2678 and 2680 are each to be a film stack of a titanium film (Ti film) (100 nm), a nickel film (Ni film) (300 nm), and a metal film (Au film) (50 nm). The terminal electrode 2678 and the terminal electrode 2680 thus obtained have fixing intensity over 5N, which is sufficient fixing intensity as a terminal electrode.

Through the above steps, the terminal electrode 2678 and terminal electrode 2680 which can be connected by solder are formed and a structure shown in FIG. 29B can be obtained. Note that from the base insulating film 2602 to the sealing layer 2676 are formed in an element formation layer 2682.

Next, a plurality of light sensor chips is taken out by cutting. A large amount of light sensor chips (2 mm×1.5 mm) can be manufactured from one large-sized substrate (for example, 600 cm×720 cm).

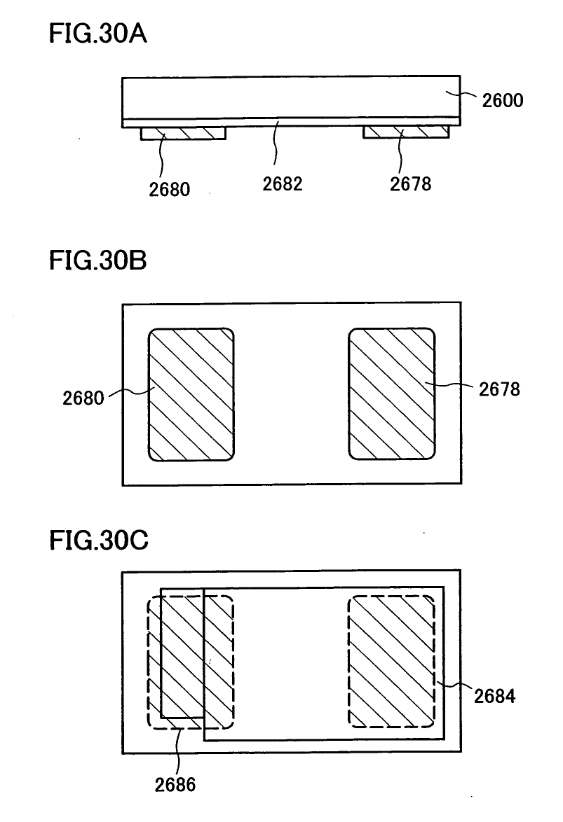

A cross-sectional view of one taken light sensor chip (2 mm×1.5 mm) is shown in FIG. 30A and a bottom view thereof and a top view thereof are shown in FIGS. 30B and 30C, respectively. Note that the total thickness including a substrate 2600, an element formation layer 2682, a terminal electrode 2678, and a terminal electrode 2680 is 0.8±0.05 mm in FIG. 30A.

In addition, in order to reduce the total thickness of the light sensor chip, the substrate 2600 may be ground to be thin by CMP treatment or the like and then cut separately by a dicer to take out a plurality of light sensor chips.

In addition, in FIG. 30B, each electrode size of the terminal electrodes 2678 and 2680 is 0.6 mm×1.1 mm, and the interval between the electrodes is 0.4 mm. Moreover, the area of a light receive portion 2684 is 1.57 mm² in FIG. 30C. Further, an amplifier circuit portion 2686 is provided with approximately 100 TFTs.

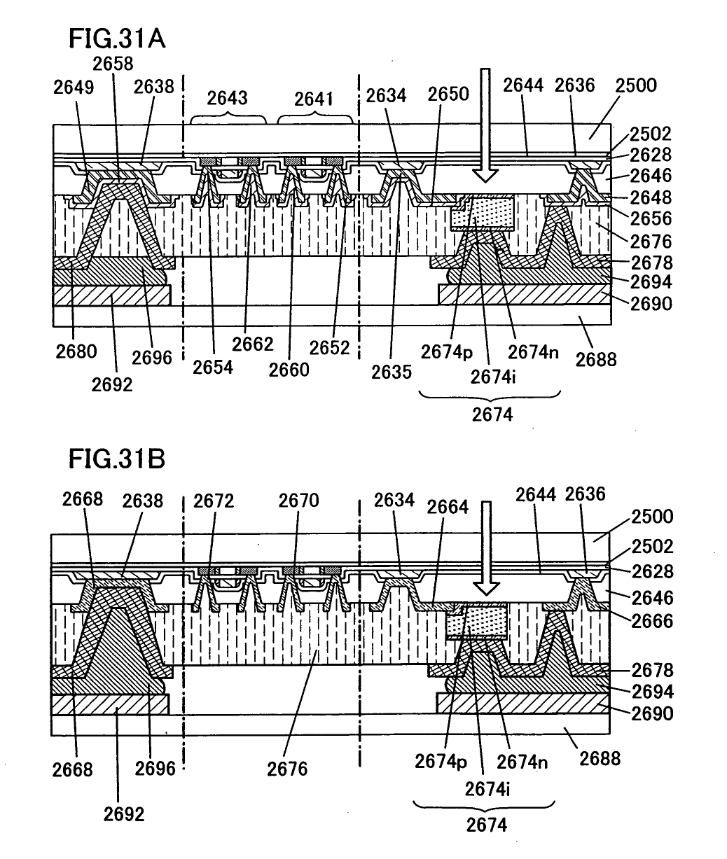

Lastly, the obtained light sensor chip is mounted on the mounting surface of a substrate 2688. Note that, in order to connect the terminal electrode 2678 to an electrode 2690 and the terminal electrode 2680 to an electrode 2692, solder is each formed over the electrodes 2690 and 2692 of the substrate 2600 by a screen printing method or the like, in advance. Then, after the solder and the terminal electrodes are connected to each other, solder reflow treatment is performed to mount the light sensor chip on the substrate 2688. The solder reflow treatment is performed at temperatures of approximately 255 to 265° C. for about 10 seconds in an inert gas atmosphere, for example. Alternatively, a bump made of a metal (gold, silver, or the like), a bump made of conductive resin, or the like can be used instead of the solder. Further alternatively, lead-free solder may be used for mounting in consideration of an environmental problem. Through the above steps, light sensor chips shown in FIGS. 31A and 31B are completed. Light is received from an arrow portion. Note that the difference between FIGS. 31A and 31B is whether there is a protective electrode or not.

This embodiment can be arbitrarily combined with the embodiment mode or other embodiments.

The present application is based on Japanese Patent Application serial No. 2005-051169 filed on Feb. 25, 2005 in Japanese Patent Office, the entire contents of which are hereby incorporated by reference.

What is claimed is:

1. A method for manufacturing a semiconductor device comprising the steps of:
forming a gate electrode over a semiconductor film;
forming a silicon nitride film over the gate electrode; and
etching the silicon nitride film by a mixed gas to leave a part of the silicon nitride film on side surfaces of the gate electrode,
wherein the mixed gas contains a hydrogen bromide gas and a chlorine gas.

2. A method for manufacturing a semiconductor device according to claim 1, wherein the semiconductor film is formed over an insulating surface of a substrate, wherein the substrate is one selected from the group consisting of a glass, a quartz, and a synthetic resin.

3. A method for manufacturing a semiconductor device according to claim 1, wherein, in the mixed gas, a ratio of a flow rate of a hydrogen bromide gas is greater than or equal to 50% based on the total flow rate of the mixed gas.

4. A method for manufacturing a semiconductor device according to claim 1, wherein the semiconductor device is one selected from the group consisting of a digital video camera, a digital camera, a reflection type projector, a display, a head-mounted display, a navigation system, an audio reproducing device, a portable information terminal, a game machine, a computer, and an image reproducing device provided with a recording medium.

5. A method for manufacturing a semiconductor device comprising the steps of:
forming a gate electrode over a semiconductor film;
forming a silicon nitride film over the gate electrode; and
etching the silicon nitride film by a mixed gas to leave a part of the silicon nitride film on side surfaces of the gate electrode,
wherein the mixed gas contains a hydrogen bromide gas and a chlorine gas and oxygen.

6. A method for manufacturing a semiconductor device according to claim 5, wherein the semiconductor film is formed over an insulating surface of a substrate, wherein the substrate is one selected from the group consisting of a glass, a quartz, and a synthetic resin.

7. A method for manufacturing a semiconductor device according to claim 5, wherein, in the mixed gas, a ratio of a flow rate of a hydrogen bromide gas is greater than or equal to 50% based on the total flow rate of the mixed gas.

8. A method for manufacturing a semiconductor device according to claim 5, wherein the semiconductor device is one selected from the group consisting of a digital video camera, a digital camera, a reflection type projector, a display, a head-mounted display, a navigation system, an audio reproducing device, a portable information terminal, a game machine, a computer, and an image reproducing device provided with a recording medium.

9. A method for manufacturing a semiconductor device comprising the steps of:
forming a gate electrode over a semiconductor substrate;
forming a silicon nitride film over the gate electrode; and
etching the silicon nitride film by a mixed gas to leave a part of the silicon nitride film on side surfaces of the gate electrode,
wherein the mixed gas contains a hydrogen bromide gas and a chlorine gas.

10. A method for manufacturing a semiconductor device according to claim 9, wherein any one of an N-type or P-type single-crystal silicon substrate, a GaAs substrate, an InP substrate, a GaN substrate, an SiC substrate, a sapphire substrate, a ZnSe substrate, and a substrate manufactured using a pasting method or an SIMOX (Separation by Implanted Oxygen) is used as the semiconductor substrate.

11. A method for manufacturing a semiconductor device according to claim 9, wherein, in the mixed gas, a ratio of a flow rate of a hydrogen bromide gas is greater than or equal to 50% based on the total flow rate of the mixed gas.

12. A method for manufacturing a semiconductor device according to claim 9, wherein the semiconductor device is one selected from the group consisting of a digital video camera, a digital camera, a reflection type projector, a display, a head-mounted display, a navigation system, an audio reproducing device, a portable information terminal, a game machine, a computer, and an image reproducing device provided with a recording medium.

13. A method for manufacturing a semiconductor device comprising the steps of:
forming a gate electrode over a semiconductor substrate;
forming a silicon nitride film over the gate electrode; and
etching the silicon nitride film by a mixed gas to leave a part of the silicon nitride film on side surfaces of the gate electrode,
wherein the mixed gas contains a hydrogen bromide gas and a chlorine gas and oxygen.

14. A method for manufacturing a semiconductor device according to claim 13, wherein any one of an N-type or P-type single-crystal silicon substrate, a GaAs substrate, an InP substrate, a GaN substrate, an SiC substrate, a sapphire substrate, a ZnSe substrate, and a substrate manufactured using a pasting method or an SIMOX (Separation by Implanted Oxygen) is used as the semiconductor substrate.

15. A method for manufacturing a semiconductor device according to claim 13, wherein, in the mixed gas, a ratio of a flow rate of a hydrogen bromide gas is greater than or equal to 50% based on the total flow rate of the mixed gas.

16. A method for manufacturing a semiconductor device according to claim 13, wherein the semiconductor device is one selected from the group consisting of a digital video camera, a digital camera, a reflection type projector, a display, a head-mounted display, a navigation system, an audio reproducing device, a portable information terminal, a game machine, a computer, and an image reproducing device provided with a recording medium.
